(19) United States
(12) Patent Application Publication
(10) Pub. No.: US 2014/0374136 A1
(43) Pub. Date: Dec. 25, 2014

(54) SUPERCONDUCTIVE TRACE PATTERNS

(71) Applicant: PST Associates, LLC, Chapel Hill, NC (US)

(72) Inventors: Michael H. Graff, Melbourne, FL (US); Douglas Torr, Chapel Hill, NC (US)

(21) Appl. No.: 14/484,363

(22) Filed: Sep. 12, 2014

Related U.S. Application Data
(63) Continuation-in-part of application No. 14/208,610, filed on Mar. 13, 2014.
(60) Provisional application No. 61/782,954, filed on Mar. 14, 2013.
(60) Provisional application No. 61/783,025, filed on Mar. 14, 2013.

(51) Int. Cl. H01L 39/00

(52) U.S. Cl. CPC H01L 39/00; H02K 53/00
USPC 174/125.1

(57) ABSTRACT

A trace is disclosed formed of superconductive material. The trace is formed in an elongate, non-linear trace pattern characterized by (i) a trace pattern thickness, (ii) a trace pattern width greater than the trace pattern thickness, (iii) a trace pattern length greater than the trace pattern width, and (iv) a trace pattern axis extending along the trace length and defining an instantaneous alignment tangential to the trace pattern axis. The trace pattern is further characterized by (i) a envelope within which the trace pattern lies and (ii) an envelope axis defining an alignment of the envelope. The trace comprises at least two electrically connected sections, where each section includes (i) a first turn in which the trace pattern instantaneous alignment rotates about 180 degrees in a first direction around a first turn focus, and (ii) a second turn in which the trace pattern instantaneous alignment rotates about 180 degrees in a second direction, opposite the first direction, about a second turn focus. The turn radius is less than about 1,000 microns.

### CROSS REFERENCE TO RELATED APPLICATIONS

This document is a continuation-in-part of U.S. patent application Ser. No. 14/208,610 entitled SYSTEM AND METHOD FOR GENERATING ELECTRICITY FROM GRAVITATIONAL FORCES filed Mar. 14, 2014, which claims priority to U.S. Provisional Patent Applications 61/783,025 entitled PSTA THEORETICAL APPROACH TO POWER GENERATION TECHNOLOGY and 61/782,954 entitled SYSTEM AND METHOD FOR GENERATING ELECTRICITY FROM GRAVITATIONAL FORCES, by Michael A. Graff and Douglas Torr both filed Mar. 14, 2013, the contents of which are herein incorporated by reference in their entireties.

### BACKGROUND

The present invention relates to producing rotational motion in a rotor through the generation of a field, such as a gravity field. More specifically, the present invention relates to using a novel winding geometry of superconducting coils to generate a field that operates on the mass of a rotor to induce rotation, which in turn can be used to drive a generator to generate electricity.

Various attempts have been made to design systems that manipulate gravitational effects to produce electricity. Such attempts have not proven successful.

### BRIEF DESCRIPTION OF THE DRAWINGS

FIG. 1 is a perspective view of an embodiment of the invention.

FIG. 2 is an exploded view of an energy transfer device according to the embodiment of FIG. 1.

FIG. 3 is an exploded view of the cryostat and superconducting toroidal coils according to the embodiment of FIG. 2.

FIG. 4 is a cross section of the cryostat according to the embodiment of FIG. 2.

FIG. 5 is a perspective view of a toroid winding support element of the embodiment of FIG. 2.

FIG. 6 is a cross sectional view of the toroid winding support element of FIG. 5 taken across line A-A.

FIG. 7 is a perspective view of a toroid winding support element with a single winding of superconductor wire.

FIG. 8 is a perspective view of a toroid winding support element and a map of the pathway taken by a superconductive wire around the toroid winding support element.

FIG. 9 shows the component of velocity projected as s function of φ onto the earth's velocity.

FIG. 10 is a perspective view of a toroid winding support element with two windings of superconductor wire.

FIG. 11 is a perspective view of a toroid winding support element with several windings of superconductor wire.

FIGS. 12A-F are cross sections of various methodologies for guiding and/or attaching superconducting wire.

FIG. 13 is a cross section of the energy transfer motor of the embodiment of FIGS. 1-3.

FIG. 14 is a schematic of an embodiment of a methodology for inducing initial motion of cooper pairs in a semiconductor.

FIG. 15 is a collection of radial cross sectional views of toroid winding support elements according to possible embodiments of the invention.

FIG. 16 is a collection of axial cross sectional views of toroid winding support elements according to possible embodiments of the invention.

FIG. 17 is a perspective view of an energy transfer device with a speed control mechanism.

FIG. 18 is a perspective view of an energy transfer device mounted on a rotating platform.

FIG. 19 is an exploded view of the inner container according to the embodiment of FIG. 2, utilizing another embodiment of a toroid winding support element.

FIG. 20 is a front view of the toroid winding support element of FIG. 19.

FIG. 21 is a front view of a portion of the toroid winding support element of FIG. 20.

FIG. 22 is a perspective view of a portion of the toroid winding support element of FIG. 20.

FIG. 23 is a perspective view of a portion of the toroid winding support element of FIG. 20 with superconducting wire laid therein.

FIGS. 24 and 25 is a map of the pathway taken by a superconductive wire around the toroid winding support element in FIG. 23.

FIG. 26 is a cross section of an embodiment of the invention with the toroid winding support element of FIG. 19.

FIG. 27 is a conceptual schematic of net torque induced by movement of copper pairs.

FIG. 28 is a perspective view of a toroid winding support element with a single winding of superconductor wire.

FIG. 29 is a zoom in view of a meandering pattern of the wire in FIG. 28.

FIG. 30 is a zoom in view of a meandering pattern of the wire in FIG. 29 with an internal meandering internal conductive pattern.

FIG. 31 is a zoom in view of a meandering pattern of the wire in a zig zag pattern.

FIG. 32 illustrates a meander pattern similar in overall geometry to that illustrated in FIG. 29 with additional labels to assist with terminology

FIG. 33 illustrates a trace pattern made of plural segments of the trace pattern illustrated in FIG. 32.

FIG. 34 illustrates a trace pattern with a 4-turn configuration.

FIG. 35 illustrates a trace pattern made of plural segments of the trace pattern illustrated in FIG. 34.

FIG. 36 illustrates a rectilinear geometry for a trace pattern.

FIG. 37 illustrates a trace pattern made of plural segments of the rectilinear geometry of FIG. 36.

FIG. 38 illustrates a single wrap of a three-dimensional, helical structure based on the trace pattern of FIG. 32.

FIG. 39 illustrates an extension of the helical structure of FIG. 38 with additional wraps around a cylinder.

FIG. 40 illustrates the extension of FIG. 39 about a cylindrical frame.

FIG. 41 illustrates an alternate extension 4102 of the helical structure of FIG. 39 using the trace pattern of FIG. 33.

FIG. 42 illustrates an application of a trace pattern of the type illustrated in FIG. 33 applied to a planar frame.

FIG. 43 illustrates a structure for a trace patter formed on a flexible substrate.

FIG. 44 illustrates across section of an alternate energy transfer device, including a rotor coupled to a generator through a shaft and shaft coupler.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

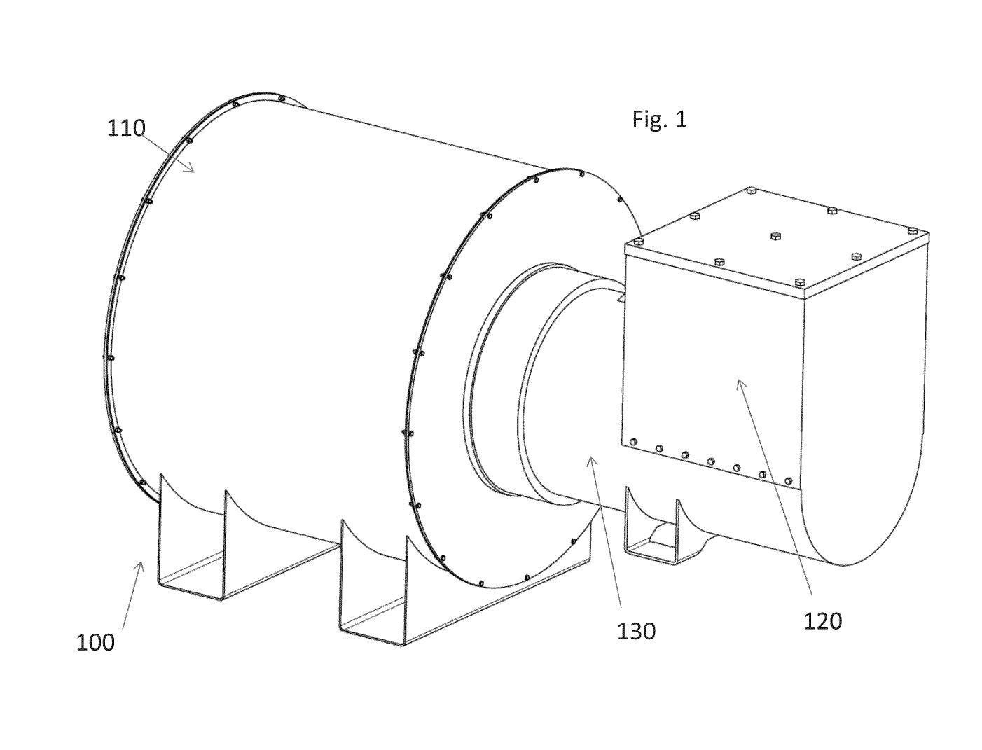

Referring now to FIG. 1, a generator 100 of the invention is shown. Generator 100 includes three sections: an energy transfer device 110, an electrical generator 120, and an interface 130.

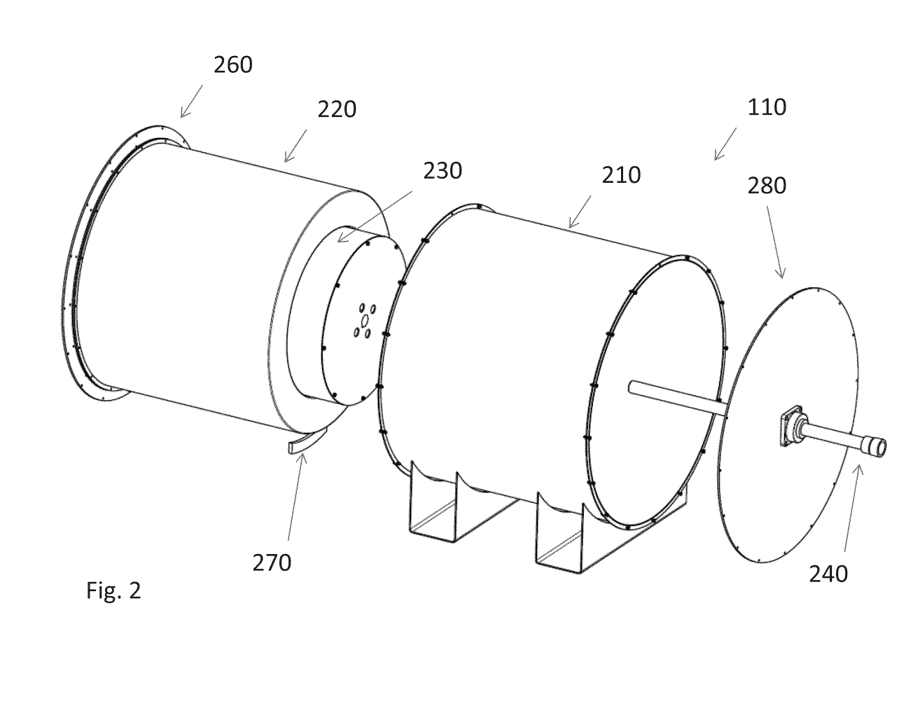

Referring now to FIG. 2, an exploded view of energy transfer device 110 is shown in more detail. Energy transfer device includes three coaxial components: an outer casing 210, an inner container 220, and a rotor 230 having a shaft 240. Supports 270 (only one is shown in FIG. 2) may be provided around the periphery of inner container 220 to support inner container 220 relative to outer casing 210.

The various components are preferably aligned as follows. The rotor 230 is mounted within an internal axial cavity of inner container 220, and the combination of rotor 230 and inner container 220 are mounted within outer casing 210. Two end plates 260 and 280 seal both ends of the outer casing 210 with inner container 220 and rotor 230 inside. Shaft 250 extends through at least one of the side plates 260 and 280 through a bearing 240 with a vacuum seal (only one side of shaft 250 so emerging from plate 280 is shown in the figures).

The various components may be assembled and/or mounted together through various support plates, welds, nuts/bolts, etc. The invention is not limited to any particular mounting and/or assembly methodology. FIG. 2 shows a non-limiting example in which rotor 230 and inner container 220 are previously mounted on plate 280; this collective component is then mounted inside outer casing 210 and sealed by plate 260.

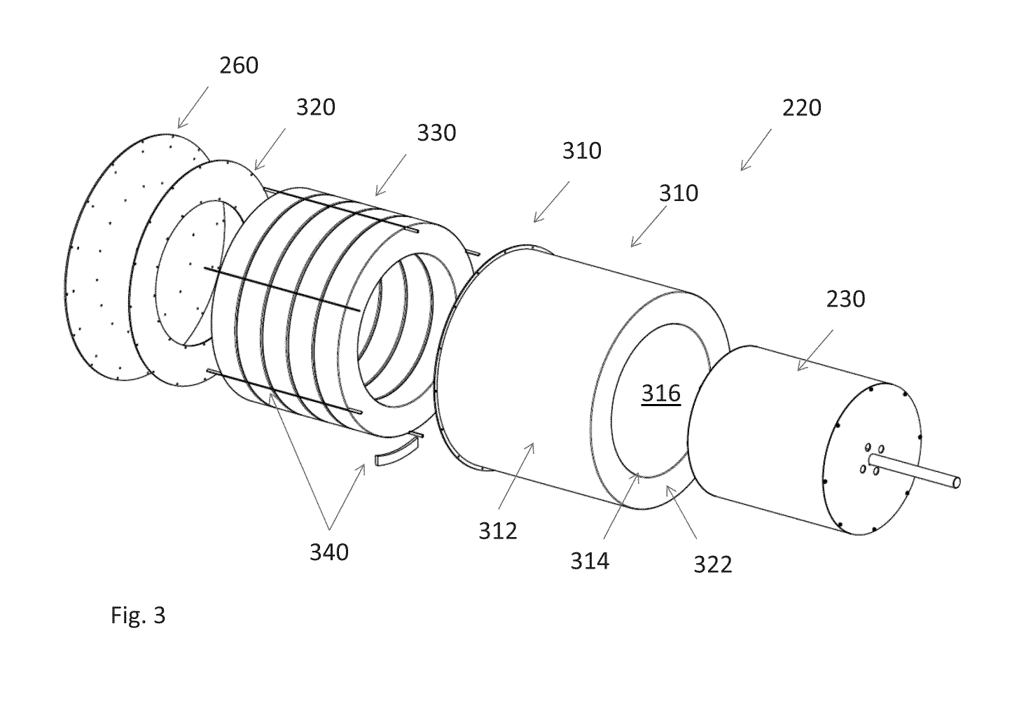

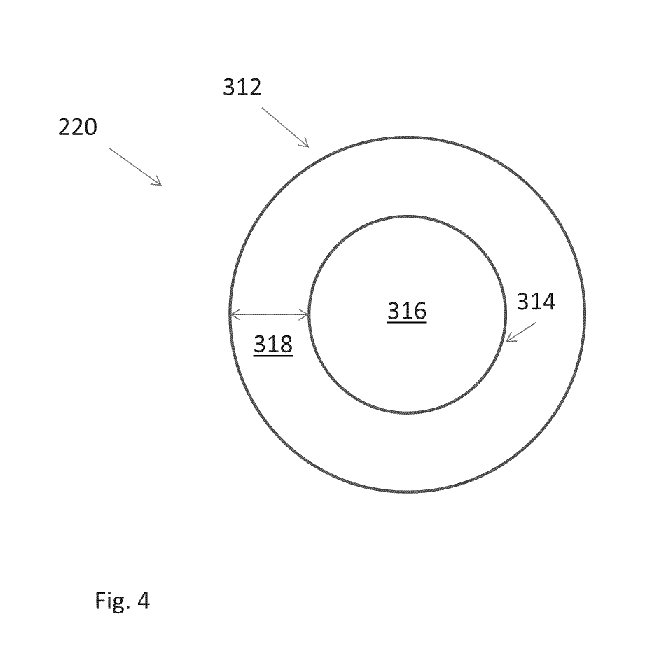

Referring now to FIGS. 3 and 4, an exploded view and cross sectional view of the inner container 220 is shown. Inner container 220 is a cryostat that maintains cryogenic temperatures of the components mounted therein. The outer portion of inner container 220 is generally defined by shell 310. Shell 310 in FIG. 3 is in the shape of toroid with a rectangular cross section, and thus has an outer wall 312 and an inner wall 314. Inner wall 314 defines an interior cavity 316 into which rotor 230 can be inserted. The space between outer wall 312 and inner wall 314 defines a cryogenic chamber 318. End plates 320 and 322 seal off the lateral ends of shell 310.

A group of toroid winding support elements 330 (five are shown in FIG. 3) with surrounding superconductor material (not shown in FIG. 3) are inserted into cryogenic chamber 318. For ease of explanation, discussion herein is limited to five (5) such toroid winding support elements. However, it is to be understood that any number (including one) may be present.

Lateral and longitudinal spacers 340 may be provided between adjacent toroid winding support elements 330 and at the lateral ends adjacent plates 320 and 322 to such that each toroid winding support element 330 is separated from other toroid winding support elements 330 and shell 310. As discussed more fully below, this gap will allow cooling fluid to circulate around toroid winding support elements 330.

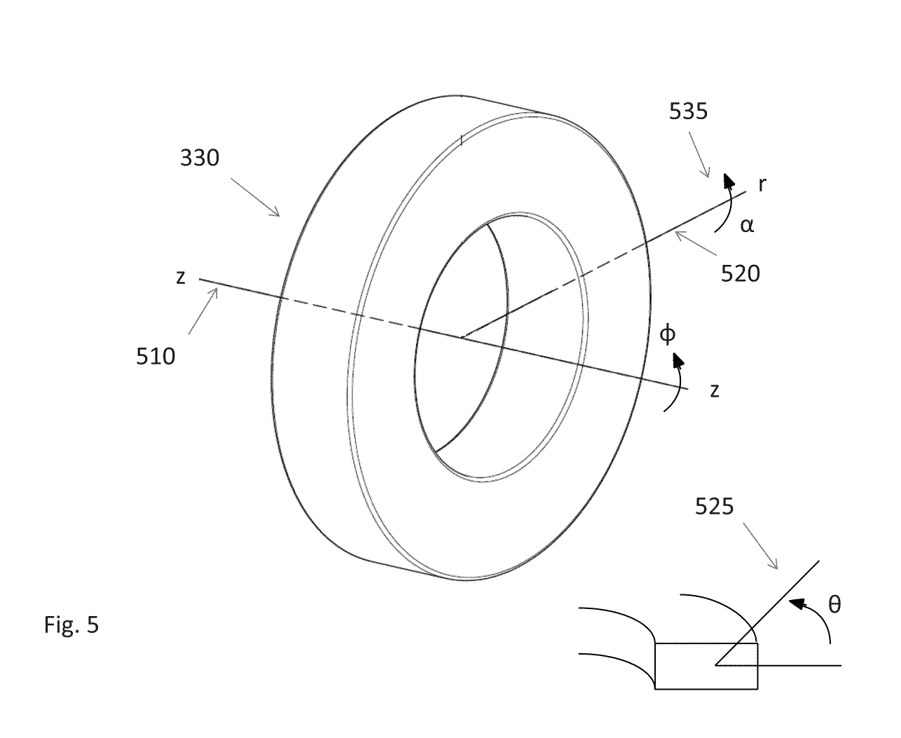

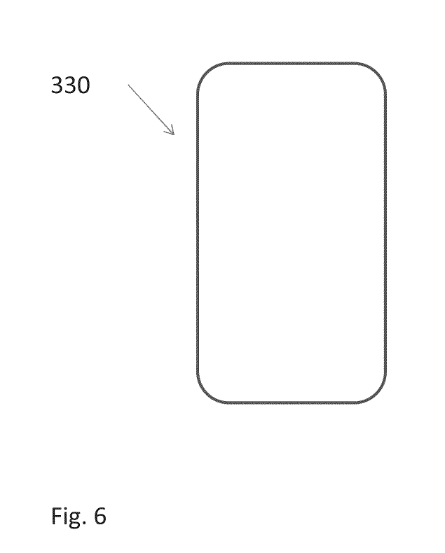

Referring now to FIGS. 5 and 6, a toroid winding support element 330 is shown. The toroid winding support element 330 preferably has a toroid shape about a central axis 510, made from a single component or multiple components connected together, that fits within inner container 220. An example of a non-limiting cross section of toroid is a substantially rectangular shape. The shape could have distinct edges, but for reasons discussed below one or more may have rounded corners or edges as shown in FIG. 6. Toroid winding support element 330 is preferably made from materials that provide physical support to superconductor windings in their operating environments, such as carbon fiber; the nature of such materials are known to those in the art of superconductors and are not discussed further herein.

A coordinate system is useful for discussing certain aspects of toroid winding support element 330. As noted above, there is a central axis Z 510. There is a radial axis R that extends through and perpendicular to the central axis Z all directions, such as 520. There is a poloidal angle 525 around the radial axis r, referred to herein as theta (“θ”). There is also a toroidal angle 530 around the central axis 510, referred to herein as phi (“φ”). Finally, there is a toroidal angle 535 around the radial axis 520, referred to herein as alpha (“α”).

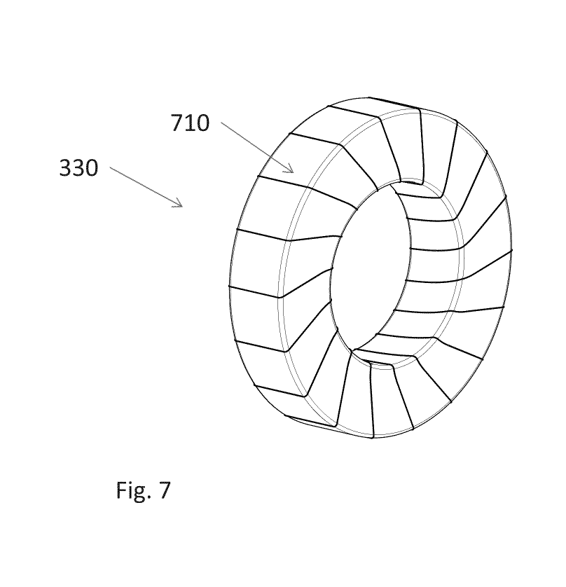

As discussed above, each toroid winding support element 330 supports a superconductor material. Referring now to FIG. 7, a superconducting wire 710 is wound around the toroid winding support element 330. Although from the figure it may appear that superconducting wire 710 forms multiple closed loops, it is in fact a single wire with two ends (not shown in FIG. 7) making multiple turns around the toroid winding support element.

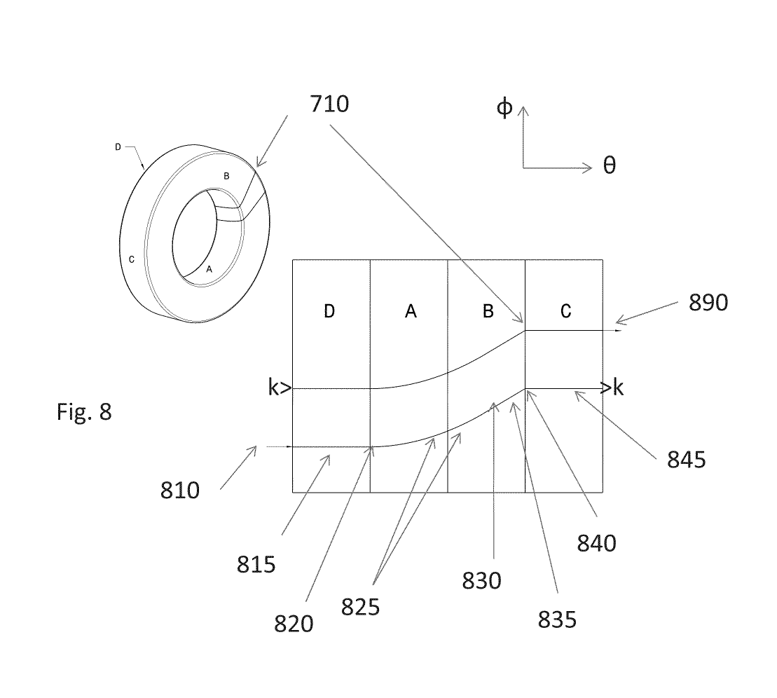

Referring now to FIG. 8, the superconducting wire 710 is wound in a prescribed pattern around toroid winding support element 330. The nature of the pattern is best described with respect to the four (4) faces of toroid winding support element, which includes the inner face A, the outer face C, and the intervening side faces B and D. These faces are illustrated in FIG. 8 for reference as unfolded onto a planar coordinate system corresponding to the θ-φ toroidal coordinates, although it is to be understood that this θ-φ representation is for illustration only.

For ease of reference, the two ends 810 and 890 of the superconductor 710 are shown at the juncture of the C and D surfaces of support 330, but it should be understood that superconductor 710 may continue beyond those points, such as for additional turns and/or to connect to other circuitry not shown.

In the embodiment of FIG. 8, superconducting wire 710 is laid along face D and runs toward face A. In this zone 815, the wire 710 is substantially linear; in the toroidal coordinate system, wire 710 does not have any change along the φ (phi) axis, but it does change in radial distance R from the central Z-axis.

At the transition of the faces D and A at 820, wire 710 is laid in a zone 825 along face A to define a curve. Non-limiting examples of mathematics that may define the particular path of the curve are discussed below. For purposes of illustration, the pathway preferably has a changing slope as viewed in the planar illustration, based on a relationship φ=θⁱ, where i>1. A parabolic curve (i=2) may be used, but other functions may be used with greater values of i preferred. In the coordinate system illustrated in FIG. 5, the pathway in zone 825 along face A is changing in the axial direction (Z) 510 and in toroidal angular direction (φ) 530, but not in radial direction (R) 520.

The curved pathway of zone 825 continues across from face A and into face B. In the toroidal coordinate system illustrated in FIG. 5, the pathway of zone 825 on face B is changing in the radial direction (R) 520 and in the toroidal angular direction (φ) 530, but not in the axial direction (Z) 520.

Over the length of zone 825, the curve may hold to a specific mathematical formula, or may vary.

Within face B, at 830 the pathway of wire 710 transitions from the curve in zone 825 to a substantially linear pathway in zone 835, i.e., i=1. In the toroidal coordinate system illustrated in FIG. 5, the pathway of zone 835 on face B is changing in the radial direction (R) 520 and in toroidal angular direction (φ) 530, but not in the axial direction (Z) 510.

At the transition of the wire pathway from face B to face C at 840, the wire 710 returns to a substantially linear pathway along zone 845. This continues along the entire surface of face C. In the toroidal coordinate system illustrated in FIG. 5, the wire 710 is substantially aligned along the axial direction (Z) 510, but does not extend in the radial direction (R) 520 or in the toroidal angular direction (φ) 530.

In the above, the transition points, such as transition point 840 may be small zones with a small but non-zero length, for example, to accommodate a minimum wire bend radius, although they are preferably significantly smaller than the other zones A, B, C and D.

The wire 710 then continues into a second turn (connected at k) onto surface of face A for a new zone 815. The winding of wire 710 continues as discussed above.

As discussed above, toroid winding support element 330 preferably has rounded corners rather than sharp ones, which facilitates winding of wire 710 around toroid winding support element 330.

The rationale for the specific layout relates to how a particle pair—particularly a cooper pair within the superconducting wire 710 under proper environmental conditions—moves along a pathway described above. Due to the nature of a superconductor, once a power supply is applied to the wire 710, cooper pairs within wire 710 under appropriate superconducting environmental conditions will continue to move through the superconducting wire 710 at a substantially constant velocity and substantially zero acceleration with respect to the entire length of wire 710.

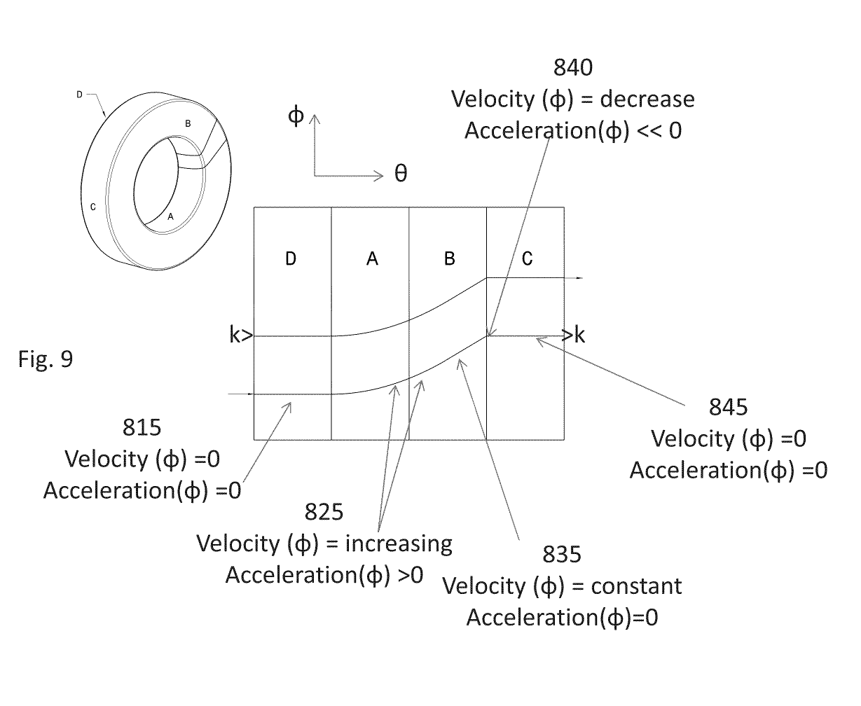

However, the velocity and acceleration are not constant with respect to the toroidal angle φ. Referring now to FIG. 9, in zone 815, there is no change in toroidal angle φ, such that for a particle the velocity with respect to toroidal angle φ (velocity (φ)) and the acceleration with respect to toroidal angle φ (acceleration (φ)) are both zero. In zone 825, the curve in the wire pathway generates an acceleration relative to toroidal angle (acceleration (φ)>0) with a corresponding increase in velocity. In zone 835, the linear nature of the wire pathway returns acceleration with respect to toroidal angle φ back to zero (acceleration (φ)=0), but maintains a velocity with respect to toroidal angle φ. At zone 840, there is a sudden shift from the angled pathway to the horizontal in zone 845. Zone 845 induces a significant deceleration with respect to toroidal angle φ (acceleration (φ)<<0) to return the velocity with respect to toroidal angle φ back to zero.

As discussed above, a characteristic of a single turn is that cumulative acceleration along a 360° turn of the toroidal angle φ remains at substantially zero. Thus, whatever acceleration created in zone 825 is offset by the deceleration in zone 840. Since zone 825 in the above embodiments is much longer than zone 840, the deceleration is particularly acute (<<0).

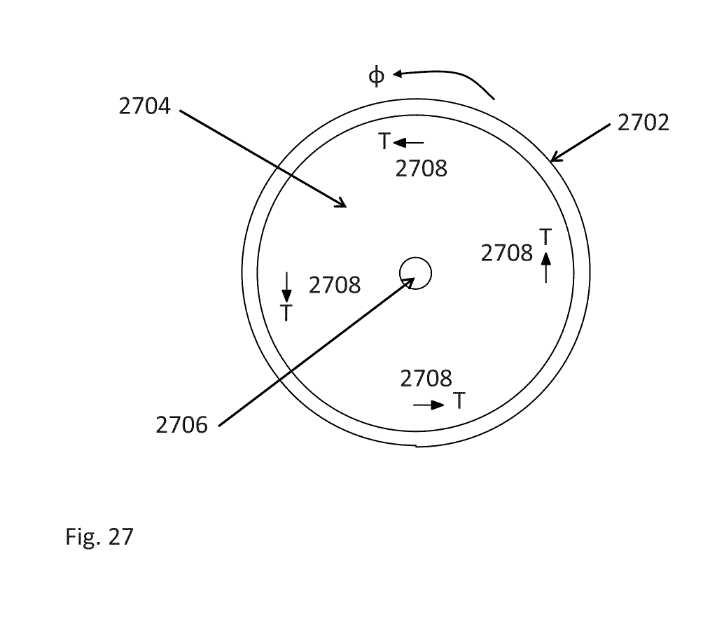

The winding pattern is based on a principle that the acceleration of cooper pairs within the superconducting windings induces a force on a nearby mass as illustrated generically in FIG. 27. Cooper pairs accelerating in phi (φ) around a ring of superconducting material 2702 induce gravitational field proportional to the magnitude of the acceleration. A mass element will experience a force in the same direction as the cooper-pair acceleration. The magnitude of the force drops off according to the square of the distance of the mass from the point(s) of cooper-pair acceleration. Rotor 2704 is mounted about a shaft 2706 concentrically within the ring 2702 will experience a net torque 2708. The winding pattern discussed with respect to FIG. 8 above is exemplary only to achieve cooper pair acceleration. Other options and overarching methodologies are discussed in more detail below in connection with the underlying scientific principles of the embodiment.

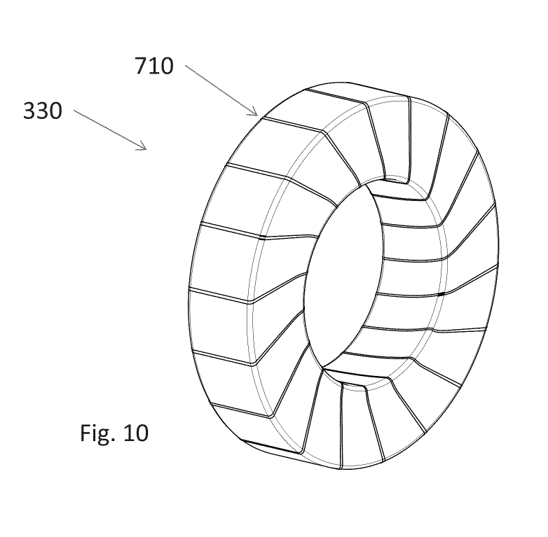

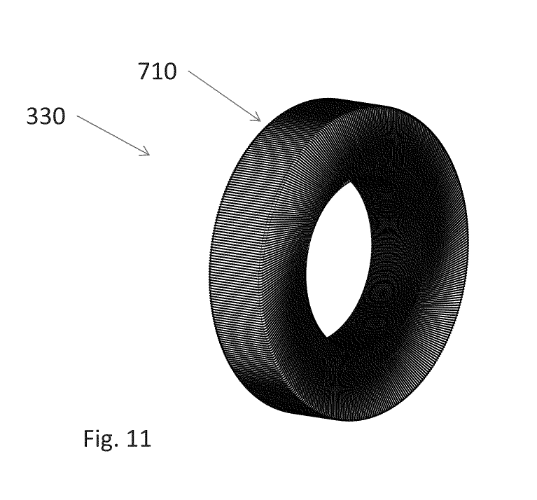

Referring back to FIG. 7, the winding pattern discussed with respect to FIG. 8 traverses completely around the toroid winding support element, that is, makes a 360-degree transit in phi (φ). The pitch (distance in the phi direction required for a single turn) may be larger than the wire diameter. Referring now to FIG. 10, the winding of superconducting wire 710 continues around supporting element 330 to interlace with the first turns; the second set of turns follows the same pattern (albeit not pathway, as there is some lateral offset) as the first set of turns. This process continues until the supporting element 330 is covered to a desired extent; FIG. 11 shows the bulk of the surface of the toroid winding support element 330 so covered.

In the above embodiment, the winding may only be one layer deep. However, the invention is not so limited, and windings may continue for several layers. Also, in the above embodiment the wire 710 is a single wire, but again the invention is not so limited, as several different wires could be so wound; provided that they would be independently actuated.

It may be desirable to provide various mechanical structures to support the laying of wire 710 in the desired pattern. One such reason for this is the effect of the Lorenz law, per which the passage of electrons though the superconducting wire in the presence of a magnetic field will generate forces that may move wire 710 from its desired position.

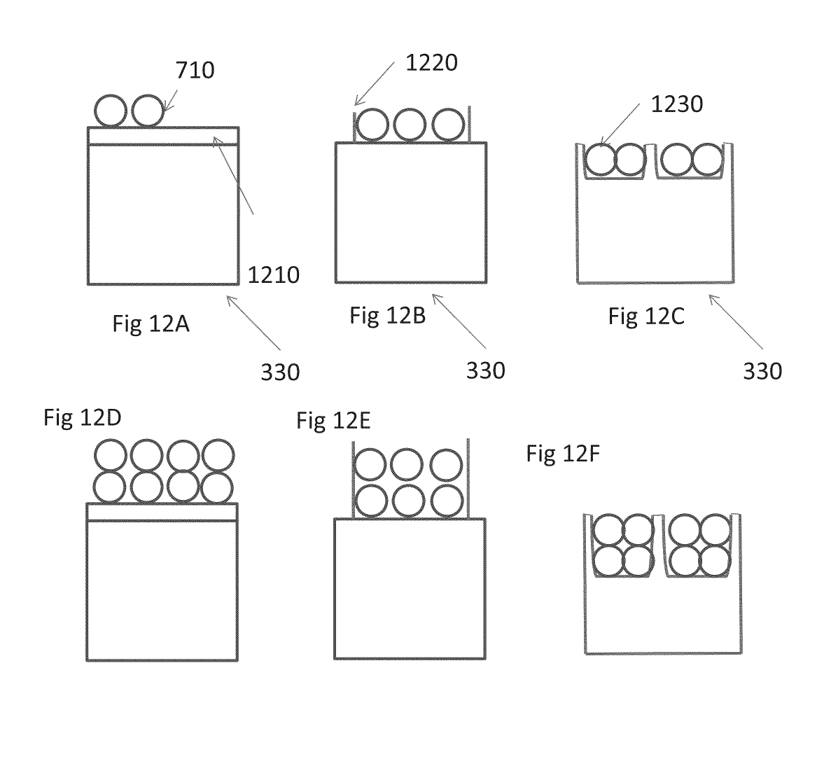

Referring to FIG. 12A, one such mechanical structure is a simple adhesive 1210 that could survive the extremely low temperatures under which superconductors operate.

Referring now to FIG. 12B, another such mechanical structure is a series of protrusions or fences 1220 along the outer surface of toroid winding support element 330 that act as guides. The fence 1220 follows the pattern shown in FIG. 8. The wire 710 is initially laid along the fence 1220, then the next winding is nested against the prior winding, and so on. There is no particular limit on the number of fences, although it may be appropriate to have one such fence per turn of wire in the winding; thus by way of non-limiting example, if there are 16 turns in the winding shown in the FIG. 7, then the fence 1220 could similarly extend continuously around the surface of toroid winding support element 330 for 16 turns. In this configuration, 99+% of the supporting element 330 could be covered with superconducting wire 710.

Referring now to FIG. 12C, another such mechanical structure is a groove 1230 cut into toroid winding support element 330. The methodology for forming grooves into toroid winding support elements to support semiconducting wires is known in the art, such as in U.S. Pat. No. 7,915,990, issued Mar. 29, 2011 entitled “Wiring assembly and method for positioning conductor in a channel having a flat surface portion”, the contents of which are expressly incorporated by reference in its entirety.

FIGS. 12D-F correspond to FIGS. 12A-C, save that the wire 710 is shown with multiple overlapping windings.

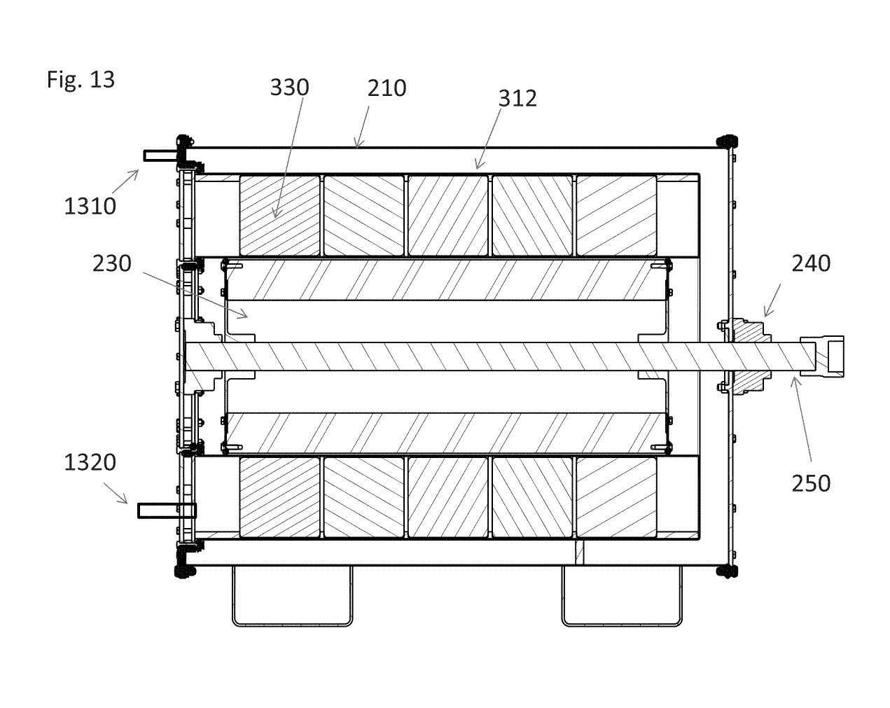

Returning to FIG. 2, toroid winding support elements 330 bearing the superconducting wires 710 are mounted inside inner container 220, and assembled in the configuration shown in FIG. 1. A cross section of the resulting energy transfer motor 110 is shown in FIG. 13.

Referring now to FIG. 13, the assembled energy transfer motor 110 is shown. A vacuum pump (not show) connects through a fitting 1310 to evacuate the area between outer casing 210 and inner container 220, and also between the inner container 220 and the rotor 230 and also between the rotor 230 and the end plates 280 and 260 and sets that area to a vacuum to provide a temperature insulator as well as eliminating friction against the rotor 230 from air. Vacuum seal 240 allows shaft 250 to transition from the vacuum inside outer casing 210 to normal atmospheric pressure outside.

Inner container 220 is filled with a liquid and/or gaseous refrigerant, which can circulate around the gaps between the supporting elements 330 established by the spacers 370. The refrigerant is of a low enough temperature to achieve the critical temperature for superconducting wire 710 to enter a superconducting state; liquid helium is suitable for this purpose, although other refrigerants as may be appropriate for the selected superconductive material of superconductor wire 710 may also be used. A cooling device 1320 may connect to inner container 220 to remove evaporating refrigerant, cool the same and return the refrigerant back to inner container 220.

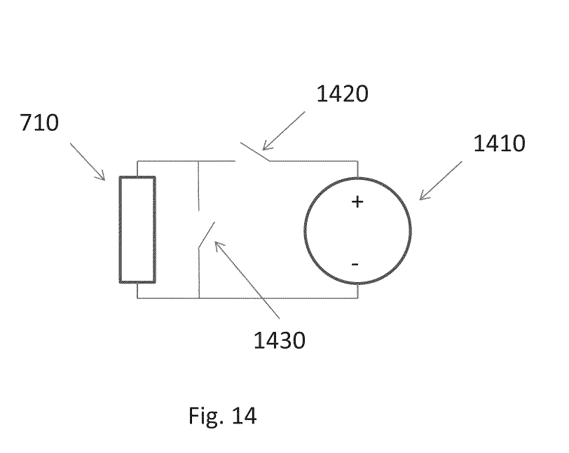

Referring now to FIG. 14, the superconducting wires 710 wound around toroid winding support elements 330 will initially require some energy to initiate movement of the cooper pairs. One such methodology is to provide wires 710 with a basic low voltage high current power supply (e.g., 1-2 volts, 1-10 k amps) or flux pump, shown in FIG. 14 generically as power supply 1410. Once the cooper pairs are energized and in motion, the power supply 1410 is disconnected via switch 1420 and the wire 710 shorted with superconducting material 1430. The methodology for initiating movement of cooper pairs in this manner is well known in the art of superconductors and not discussed further herein. Power supply 1410 could be positioned inside or outside of external casing 210, provided appropriate interfaces were provided to reach wires 710. The methodology for initiating this internal motion is known to those of skill in the art of superconductors, and not further described herein.

The operation of the energy transfer motor will now be discussed. The cooper pairs are energized within superconductive wire 710 as discussed above. As is known in the art, superconducting wire 710—which is below its critical temperature due to the refrigerant—will allow the cooper pairs to circulate indefinitely within the windings around toroid winding support element 330.

When the cooper pairs are in a geometric zone in which they are accelerating with respect to phi, such as for example zone 825, the cooper pairs will generate a corresponding gravitational field. This field exerts a torque on rotor 230 causing it to rotate around axis 510, which coincides with shaft 250.

Similarly, when the cooper pairs are in a zone in which they are decelerating such as zone 840, the cooper pairs will generate a corresponding field in the opposite direction to zone 825.

Since the total acceleration of the cooper pairs around a turn is equal to zero, the acceleration-induced torque could offset the deceleration. Further, the field generated by the deceleration, by virtue of its opposite direction, counteracts the effects applied by the field generated by acceleration.

However, while the field created by acceleration and deceleration of the cooper pairs are equal, they do not have equal effects on rotor 230. This is because the zone of acceleration 825 is primarily on the internal face A of toroid winding support element 330, which is closest to rotor 203. In contrast, the zone of deceleration 840 is at the transition of face D and C, which is further away from the rotor than the zone of acceleration. Based on a principle that the effect of the field component is proportional to 1/r² (where r is the distance from the point of cooper-pair acceleration to a mass element), the further a zone is from the rotor 230, the less influence it will have. As a result, the torque induced by the proximate zone of acceleration 825 is greater than the counter torque induced by the zone of deceleration 840. Thus, there is a non-zero net effect on the rotor 230, which exerts a torque to rotate rotor 230.

The embodiment of FIG. 7 uses a wiring path with zone of acceleration 825 occurring at a different distance from rotor 230 than zone of deceleration 840. Other configurations in which the areas closer to rotor 230 generate net positive (or negative) acceleration while the areas further from rotor 230 generate net negative (or positive) cooper-pair acceleration may be used.

Further, the layout of wires 710 does not require perfection in mechanical accuracy to produce this result. There may be an optimal layout that will generate the greatest overall torque, and mechanical accuracy may yield the most perfect implementation of that design. Yet the design still works absent that accuracy, and relaxation of the accuracy may allow for more wire 710 to be laid (e.g., wire 710 laid in fences 1220 is less accurate than grooves 1230, but fences 1220 may allow for more wire 710) to generate higher overall torque yield.

All of the above being said, the velocity of movement of the cooper pair through wire 710 in and of itself may not be sufficient to generate a desired amount of torque on rotor 230. A velocity component may be exploited to contribute to the field.

Such a velocity component is in fact available, as the cooper pairs are moving relative to Earth, which is in turn moving relative to a position in space. More specifically, the Earth as a celestial body is moving away from the origin point of the universe. The Earth is moving through space in a direction approximate to the true north-south axis of the Earth, and at a speed of approximately 1.3% of the speed of light. For discussion purposes this is referred to herein as Earth velocity. Although the foundation of the same is not necessary for implementation of the embodiments discussed herein, by way of reference the underlying physics is discussed in more detail in Applicants' incorporated by reference U.S. Provisional Patent Application entitled PSTA THEORETICAL APPROACH TO POWER GENERATION TECHNOLOGY.

Under theories of relativity, energy from the Earth velocity ordinarily cannot be harnessed because any particle from which it would be harnessed is moving in the same speed and direction as the environment that supports the particle; relative to each other, the particle and the environment do not have such energy to capture. However, such relativistic relationship breaks down in the environment of operating superconductors.

Since the energy of Earth velocity is not omni-directional, but rather in the specific direction of approximately the true north-south axis of the Earth, energy transfer device 110 benefits from an orientation to capture the effect of the Earth's velocity on the cooper pairs. (By way of analogy, a boat sail must be in a particular orientation to capture the wind, although the underlying physics is different.) To capture that energy, the central axis 510, and thus shaft 250, is preferably aligned perpendicular to the direction of Earth velocity, i.e., approximately on an east-west orientation.

When in this orientation and under superconducting environmental conditions, the velocity of the cooper pairs as measured relative to the Earth becomes only a portion of the overall kinetic energy, in that the Earth velocity is approximately 1.3% of the speed of light. The effect of the cooper pairs is proportional to the product of their velocity (as measured with respect to the Earth) and the relatively large absolute velocity of the Earth (as measured in a frame of reference attached to the universe point of origin). The field generated from cooper-pair acceleration that is aligned with the Earth's velocity is significantly greater, and sufficient to effectuate a rotational torque on rotor 230.

An angular variation off that alignment reduces the harnessable energy. Thus, minor variations within 20 degrees may not result in much loss, although higher amounts will begin to have more impact. Orienting the shaft 250 parallel with the direction of Earth velocity would fail to harness any of the Earth velocity.

Returning now to FIG. 1, energy transfer device 110 drives an electrical generator 120 through an interface 130. Electrical generator 120 may be any type of device as known to convert rotation into electricity not discussed further herein. Interface 130 connects shaft 250 to the electrical generator 120, such that rotation of the shaft 250 causes generator 120 to generate electricity. Interface 130 may be a mechanical interface of connecting gears, or may simply be the mechanical space by which shaft 250 extends toward and connects directly to electrical generator 120.

The above considerations in some cases drive various design parameter and options of the embodiments, while others are not. Several examples are as follows.

Rotor 230 is the disclosed embodiment is a hollow cylinder to which shaft 250 is attached via end plates. However, the invention is not so limited. Rotor 230 could be solid or hollow. Rotor 230 and shaft 250 could be integral or separate components. Rotor 230 and/or shaft 250 may be made of the same materials or different materials.

The material composition of rotor 230 and/or shaft 250 can be any suitable material for the environmental conditions under which these components rotate. A dense metal such as stainless steel may be used. A combination of carbon fiber exterior around a lead interior is a non-limiting example of composite materials that can be used for the rotor.

The external shape of rotor 230 has no particular design limits other than efficiency, and would typically (but not necessarily) be cylindrical. As discussed above, the torque applied by the superconducting wire 710 is strongest proximate to the wire and drops off by a factor of 1/r² as the distance increases. So the outer portion of the rotor 230 is preferably (a) as close as possible to inner container 220 while still allowing for a gap there between with sufficient tolerance that rotor 230 can freely rotate, and (b) match the shape of the inner container 220 as closely as possible. From an efficiency standpoint, this is preferably achieved with a cylindrical rotor mounted within a toroid shape inner container 220, and the toroid winding support elements 330 having a flat surface A as discussed above. However, the invention is not so limited, and other designs may be used. A toroid having an inner diameter of 100 cm, and outer diameter of 140 cm, and an axial length of 100 cm may be appropriate.

Toroid winding support element 330 may be any material that can provide the structural support for wire 710 and withstand the operating conditions (e.g., low temperatures) under which superconductors operate. Carbon fiber is a non-limiting example of such a material. The scope of appropriate materials is known to those of skill in the art of superconductors and is not further discussed herein.

The shape of toroid winding support element 330 has no particular design limits other than efficiency. The portion of the wire 710 that is closest to the rotor 230 provides the maximum torque, and thus for efficiency the corresponding area of toroid winding support element 330 (face A) in the toroidal angle direction is preferably cylindrical in the φ direction to provide uniform application. The overall rounded rectangular shape discussed herein with respect to FIG. 6 also provides an easy and uniform surface for winding purposes, as well as providing dedicated areas for the zones of deceleration that are as far as possible from the rotor 230.

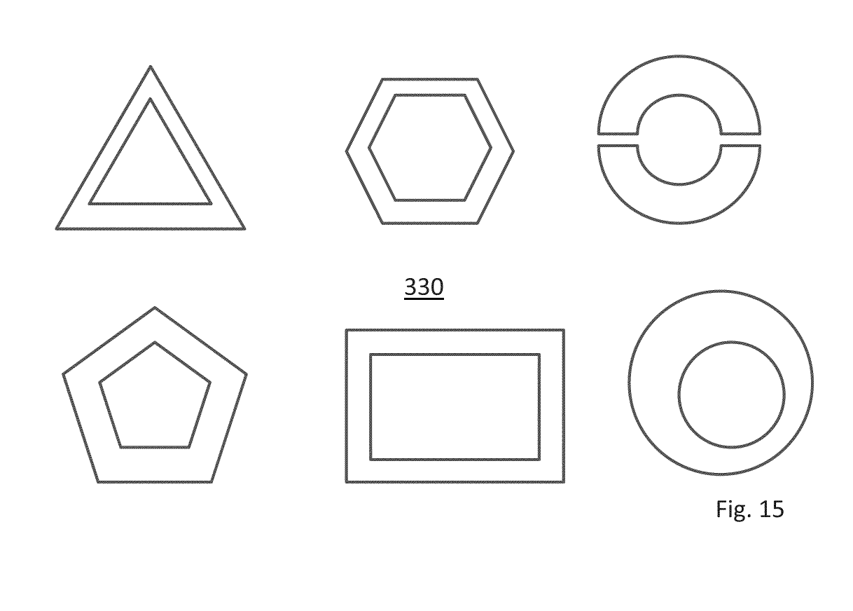

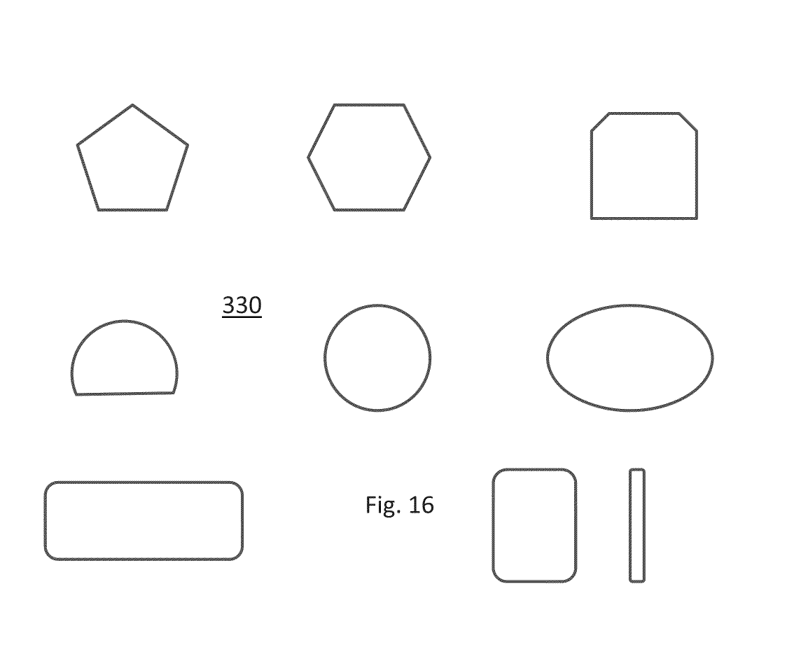

However, the invention is not so limited, and other shapes could be used, such as pentagons, hexagons, ring (a very thin rectangle) etc., whether of uniform shape or non-uniform shape. Toroid winding support element 330 may be a single uniform structure, several connected structures, and/or several unconnected structures in proximity to each other. Thickness may be uniform around the central axis, or non-uniform. FIG. 15 shows various non-limiting examples of cross sections of toroid winding support element 330 relative to φ that illustrate these various possibilities. FIG. 16 shows various non-limiting examples of cross sections of toroid winding support element 330 relative to axial and radial directions that illustrate these various possibilities.

As discussed above, any corners of toroid winding support element 330 are preferably rounded to facilitate winding. However, there may be situations, particularly with the use of grooves 1230, where the grooves 1230 have a different shape than the outermost portion of toroid winding support element 330. For example, even though toroid winding support element 330 may have sharp corners, the grooves may be formed to a different depth around the corners, such that the bottom of the grooves provided a rounded surface.

Toroid winding support elements 330 are shown herein as of the same shape and size. While this design promotes efficient operation, the invention is not so limited, and different toroid winding support elements may of different size, shape, and/or material composition.

Further, while toroid are described herein as having various shapes, e.g., square or rectangular, this does not imply and should not be defined to require precision to such shapes. As noted herein, the outer surface of the toroid may have various modifications, e.g., rounded corners, grooves, fences, etc. The discussion of any particular shape or size herein carries a “generally” or “substantially” modifier, e.g., a “rectangular toroid” is a generally rectangular cross section toroid, and includes allowance for surface modifications as discussed herein, imperfections and other minor variances from ideal.

Toroid winding support elements 330 are preferably separated from themselves and the walls of inner container 220 by spacers 370 to allow refrigerant to circulate around superconducting wire 310. Spacers 370 are made of any material that can withstand the operating conditions. Ceramic may be appropriate for this, although the invention is not limited thereto. Spacers 370 may be individually placed around the various components, although as an alternative spaces 370 may be one large rack that holds supports 330 and is loaded into inner container 220 as a unit.

The embodiments herein show five toroid winding support elements 330. However, the invention is not so limited. The design is scalable, and can have less or more toroid winding support elements. The number would be based on the shape of each toroid winding support element and the size of the shell 310, all of which would be at least partially based on the desired ultimate output power of 100.

Superconducting wire 710 is described above as a single wire winding around a toroid winding support element 330. However, the invention is not so limited, and multiple wires may be used so long as each has some initial driving force 1410 discussed herein. In the alternative, the same wire could be wound around multiple toroid winding support elements 330. Different wires 710 are preferably of the same material and thickness, although this need not be the case.

The device power can be scaled by increasing the diameter of the rotor 230 with corresponding increases in size of the surrounding components. The larger the rotor, the greater the torque generated.

The device can be further scaled by increasing the rotation rate of the rotor at any given diameter, within the constraints of the material properties of the rotor.

As is known in the art, superconducting wires include filaments of superconducting materials, along with various other non-superconducting materials that provide strength and/or insulation that collectively provide a medium of near zero electrical resistance when in the superconducting state. Niobium compounds, such as Niobium-tin or Niobium titanium are preferable for wire 710, but the invention is not so limited. The wire 710 is preferably on the order of 1 mm in diameter, but other sizes could be used. The wire is preferably made from 25 k filaments on the order of 3 microns each, but other numbers of filaments and sizes could be used. Any type of superconductor could be used.

Another non-limiting example is a thin film wire, such as yttrium barium copper oxide found in for example SuperPower® 2G HTS Wire. Such wire could be laid as described herein. As a thin film product, the structure could also be grown on the support directly. In such case this is to be considered a form of winding as discussed herein.

The scope of appropriate materials and designs of superconducting wire is known to those of skill in the art of superconductors and is not further discussed herein.

For a wire 710 made from a Niobium compound, an extremely low temperature refrigerant is preferred, such as liquid helium. However, the invention is not so limited, and any refrigerant as appropriate to induce the superconducting properties (e.g. establish a temperature below approximately 10 degrees Kelvin) in the wire 710 may be used. The scope of appropriate refrigerants is known to those of skill in the art of superconductors and is not further discussed herein.

Wire 710 as shown in FIG. 7 preferably is turned 16 times around the circumferences of toroid winding support element 330 for a single revolution; however, the invention is not so limited, and an number of turns may be made. Wire 710 of 1 mm diameter can be nested at a 2 mm pitch, although other pitches may be used. For a toroid winding support element 330 of ½-meter inner diameter, a total of 50 nested windings may be used, although the invention is not so limited and any number may be used. Preferably the windings adjacent the rotor are in parallel, and thus provide a uniform field, although the invention is not so limited.

The winding pattern of wire 710 as shown in FIG. 8 is exemplary only. As discussed above, any pattern that induces asymmetrical effects of acceleration and deceleration on rotor 230 can be used. For example, face A could include zones of acceleration, zones of deceleration, and zones of no acceleration. The only limiting factor is that the winding pattern as a whole create a net torque (clockwise or counterclockwise) on rotor 230.

Shell 310 of inner container 220 is designed to hold toroid winding support elements 330 in the refrigerant. Inner wall 314 will generally conform to the shapes dictated by the toroid winding support elements 330 and the rotor 230. One end of the shell will be attachable to seal (e.g., via welding) inner container 220 after toroid winding support elements 330 are loaded therein. The other end of the shell can be either attachable or integrally formed with inner wall 314 and outer wall 312. Outer wall 312 can have any shape, but to minimize the volume of refrigerant preferably follows the outer shape of the toroid winding support elements 330. Shell 310 may be made of any material that can survive the environmental conditions, such as by non-limiting example stainless steel.

Outer casing 210 surrounds inner container 220. Outer container 210 is preferably made from a material that can withstand the surrounding conditions (e.g., an interior vacuum), such as stainless steel. The shape of outer counter 210 is preferably dimensioned to allow for sufficient insulation, but any design could be used.

As noted above, the architecture herein is scalable. Overall, the design considerations prefer the largest maximum current of cooper pairs, which may entail a balance between selection of superconducting wire for maximum critical current vs. diameter and winding geometry. Other design consideration include increasing total number of turns for windings, making toroid winding support elements 330 thinner to increase effective acceleration in φ (which may requires more but smaller toroid winding support elements to extend to length of rotor), and increasing the radius of the toroid winding support element 330 and rotor 230. Fences 1220 or grooves 1230 could be made higher/deeper to allow for multiple overlapping windings, such as shown ion FIGS. 12E and 12F.

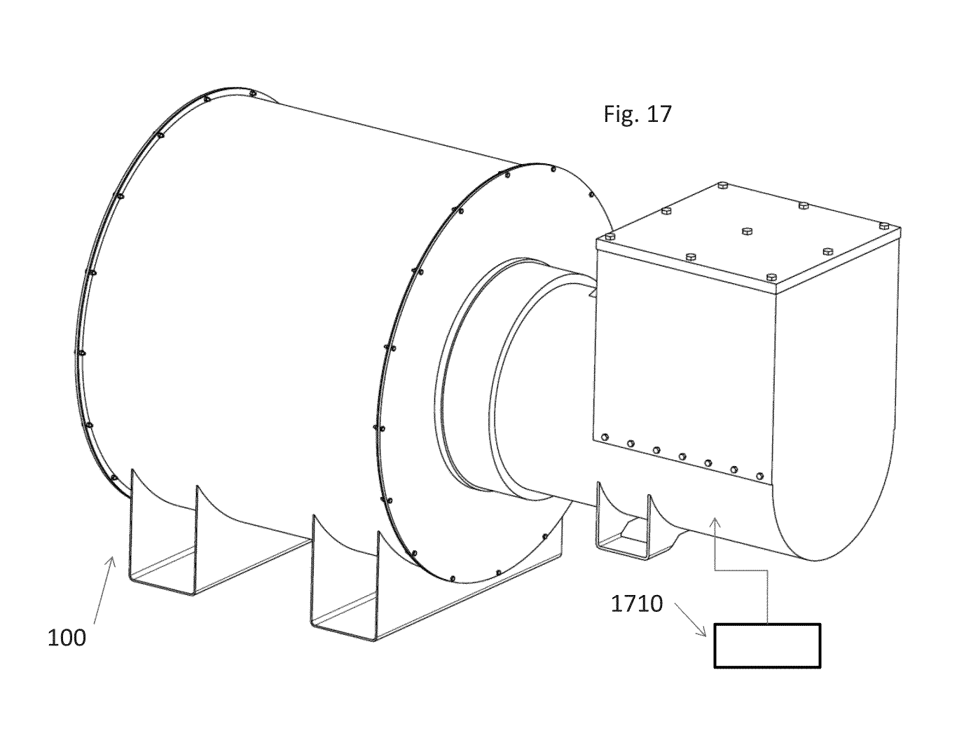

The rotational torque on rotor 230 can induce a rotational acceleration that may require some level of control, by way of non-limiting example to limit the rotation rate of the rotor or to match the frequency of an electrical grid. There are a variety of options for such control. Once such method is to generate a counter torque by controlling the generator field that results in the generator opposing rotation of shaft 250 in accordance with the field current. Alternatively, a physical or magnetic brake can be used to counter the torque generated by the rotor. These are all generically represented by speed control mechanism 1710 in FIG. 17.

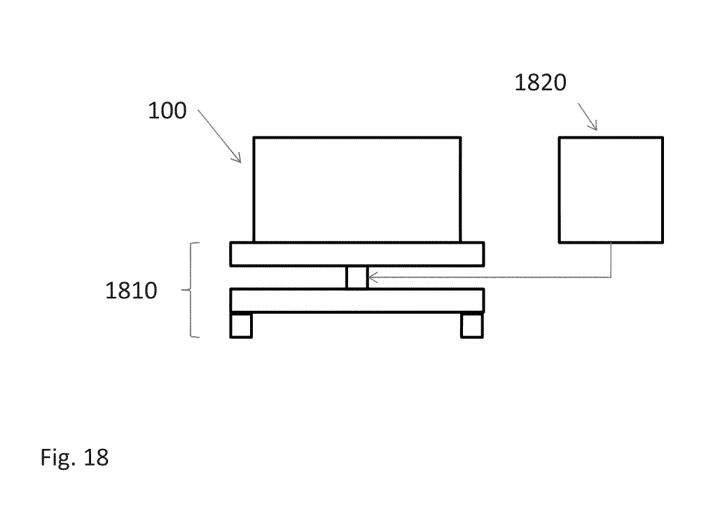

Referring now to FIG. 18, yet another method is to mount the transfer motor 110 on a moveable/rotating platform 1810 that can adjust the angle of the shaft 250 relative to the Earth velocity. As discussed above, maximum energy output exists when the central axis of motor 110 is perpendicular to the Earth velocity, and the output drops off as the angle alignment deviates from that perpendicular. The platform can be controlled electronically via controller 1820 to move the motor 110 into optimal alignment to achieve that maximum power level and similarly to move motor 110 out of optimal alignment to decrease power output or to react to emergency conditions. This control method may also be used to operate the energy transfer motor in a mobile environment, such as the engine of a locomotive. In theory, motor 110 could be placed into one alignment to achieve initial rotation, and then moved into a less optimal position which the applied acceleration is counteracted by other environmental effects such that the rotation of rotor 230 remains substantially steady.

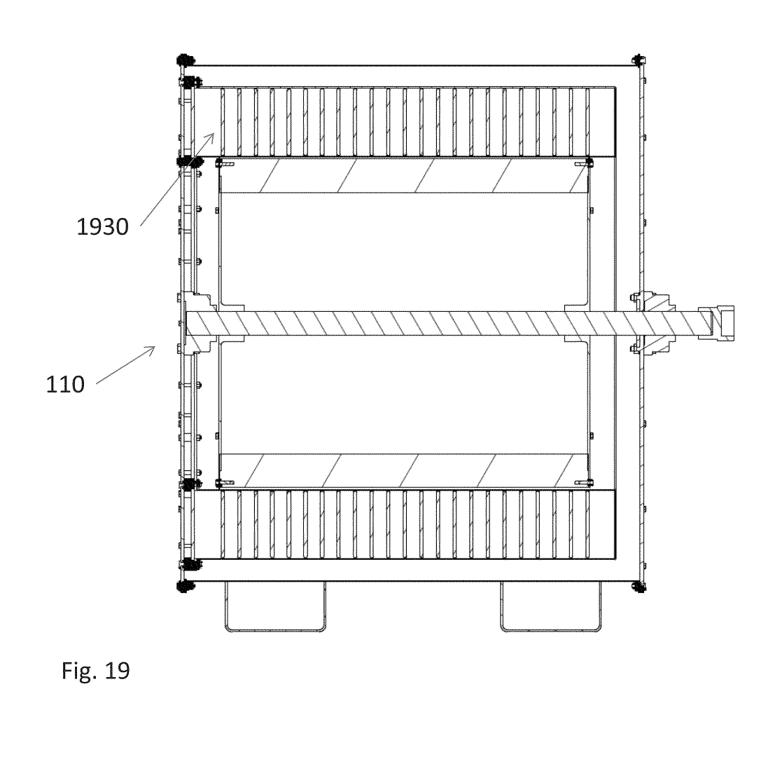

Referring now to FIG. 19, another embodiment of a toroid winding support element 1930 is shown within motor 110. In this embodiment, toroid winding support element 1930 is a narrow rectangular toroid. For ease of discussion, toroid winding support elements 1930 are shown in FIG. 19 as having a certain thickness and distance between adjacent ones. While the embodiment could be implemented this way, toroid winding support element 1930 may be even thinner than shown, and much closer to each other (separated by sufficient minimal space to allow coolant to circulate).

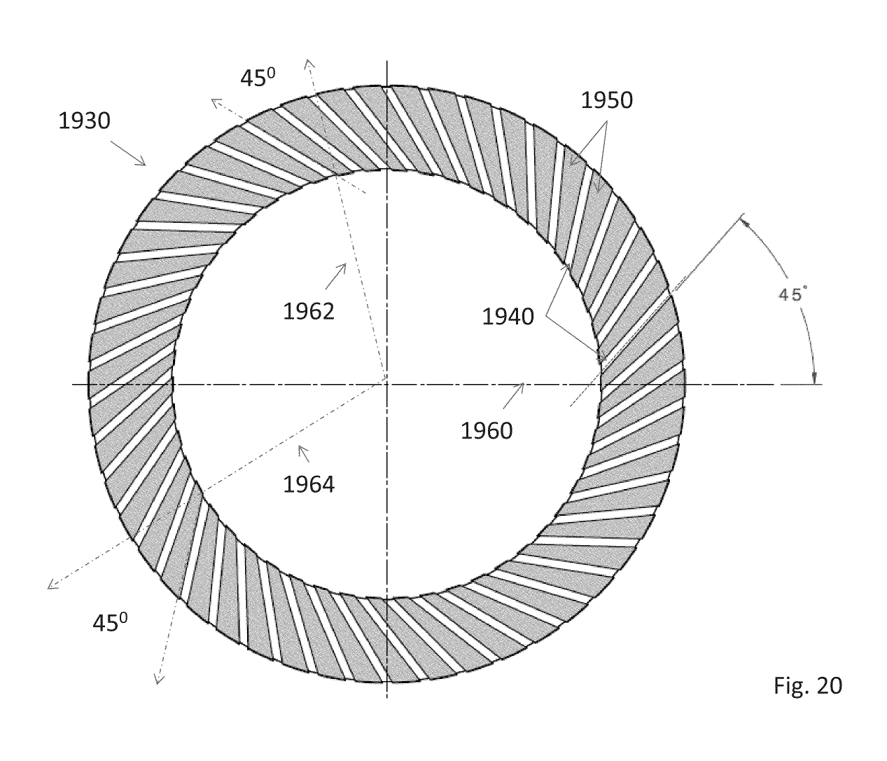

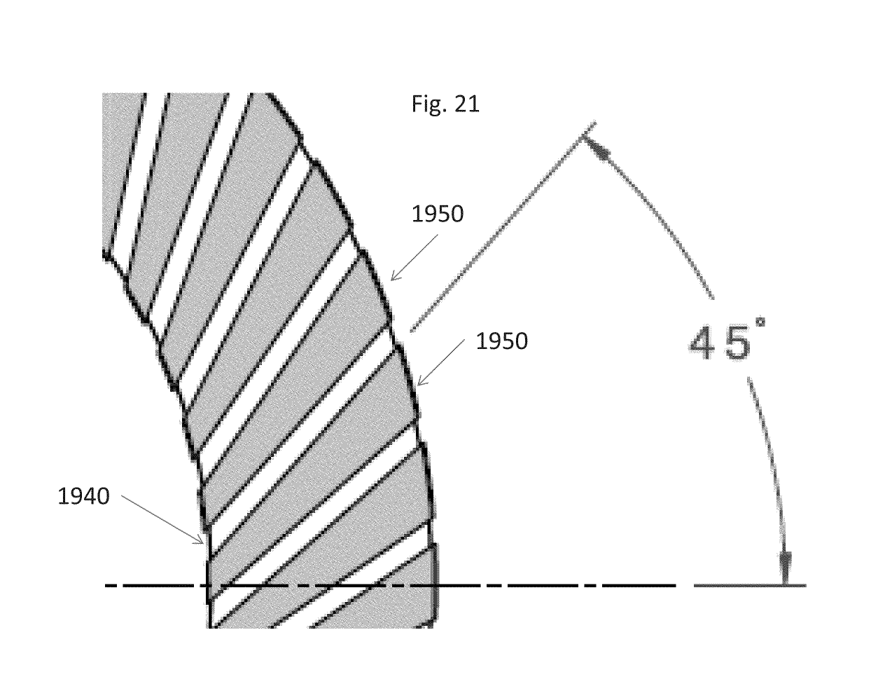

Referring now of FIGS. 20-22, toroid winding support element 1930 is shown in more detail. Toroid winding support element 1930 includes wiring channels or grooves 1940 separated by sidewalk 1950 (this arrangement can be thought of as grooves per FIG. 12C or fences per FIG. 12B, depending the nature of the supporting design).

Each groove 1910 preferably has several characteristics. One such characteristic is that each groove 1940 is at a substantially equal angle to a radial extending from the central axis of the toroid winding support element 1930 (which as described above is coaxial with the rotor 230). As can be seen in FIG. 19, groove 1940 is at a 45-degree angle relative to the lateral radial shown at 1960. Similar 45-degree angles are show for radials 1962 and 1964.

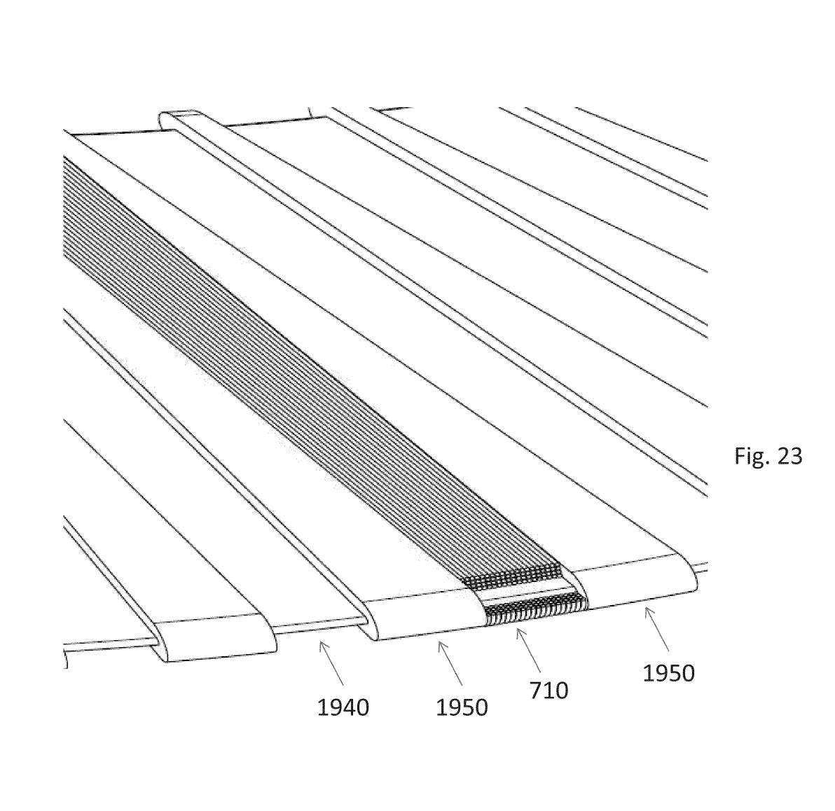

Referring now to FIG. 23, superconducting wire 710 is wound in a groove 1940. The wire 710 in FIG. 23 is artistically cut away to reveal the depth of the overlapping winding within groove 1940, although it is to be understood that the wires 710 wind fully around groove 1940. In this embodiment, wire 710 is fully wound around groove 1940 before being wound on the next groove, etc. However, the invention is not so limited. The wire could be partially laid in each groove as described with respect to FIGS. 10 and 11. Multiple wires 710 could be used, e.g. one for each groove 1940. The invention is not limited to the number of wires 710 and or the manner in which they are would relative to any particular groove/fence.

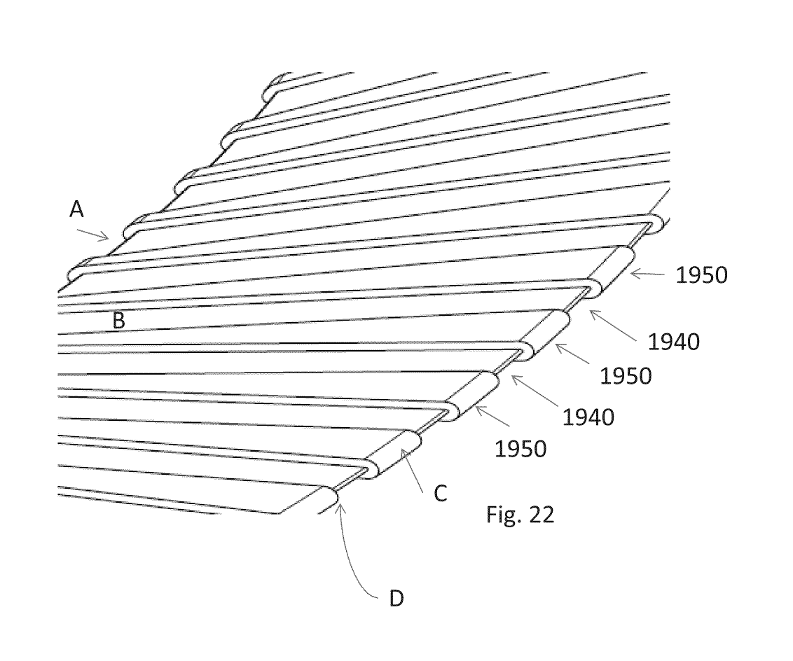

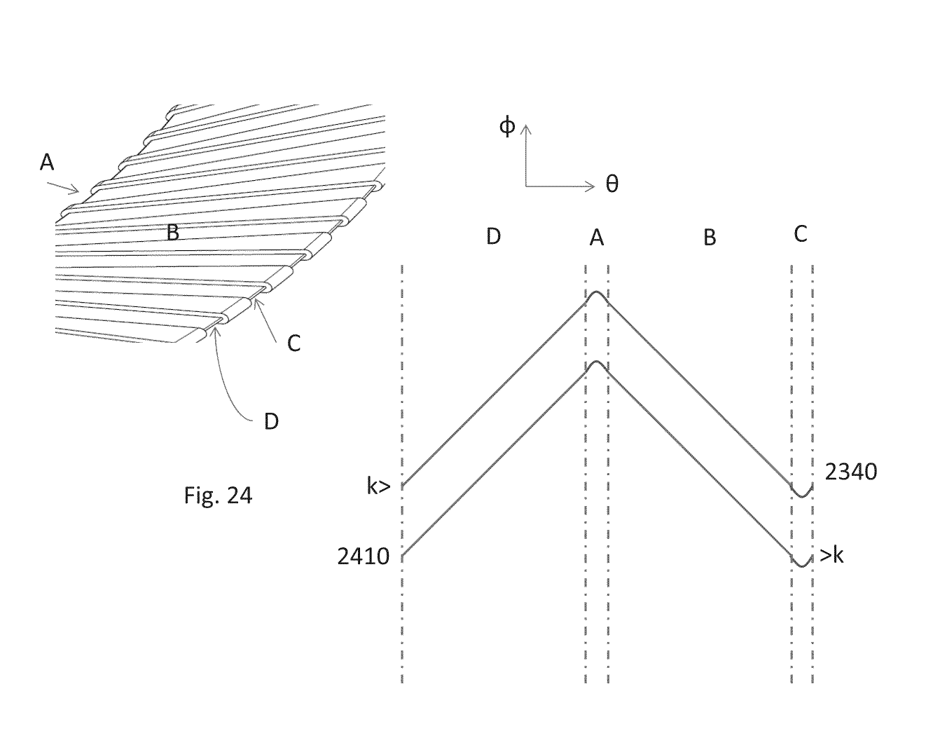

Referring now also to FIG. 24, the groves 1940 define a specific pathway for superconducting wire 710 in a specific pattern around toroid winding support element 1930. The nature of the pattern is best described with respect to the four (4) faces of toroid winding support element, which includes the inner face A, the outer face C, and the intervening side faces 13 and D (shown in FIG. 22). These faces are laid flat in FIG. 24 for illustration in a planar coordinate system, although it is to be understood that the view is for reference only, and the toroid winding support element 1930 forms a three-dimensional toroidal shape.

For ease of reference, the two ends 2310 and 2390 of the superconductor 710 are shown at the juncture of the C and D surfaces of support 1930.

In the embodiment of FIGS. 23-24, superconducting wire 710 is laid along face D and runs toward face A to define a straight angled tine at an angle defined by the groove 1940. At face A, which is effectively an inner edge of toroid winding support element 1930, wire 710 is laid thereabout to define an abrupt curve. The pathway of wire 710 then almost immediately transitions to face B, in which the wire 710 proceeds to define a straight angled line defined by the groove 1940 toward face C. At face D, which is effectively an outer edge of toroid winding support element 1930, wire 710 is laid around the edge to again define an abrupt curve. The pathway then continues back to face A as discussed above.

The rationale for the specific layout relates to how a particle—particularly a cooper pair within the superconducting wire 710 under proper environmental conditions—moves along a pathway described above. Due to the nature of a superconductor, once a force is applied the cooper pair, it will continue to move through the superconducting wire at a substantially constant velocity and substantially zero acceleration with respect to the entire length of wire 710.

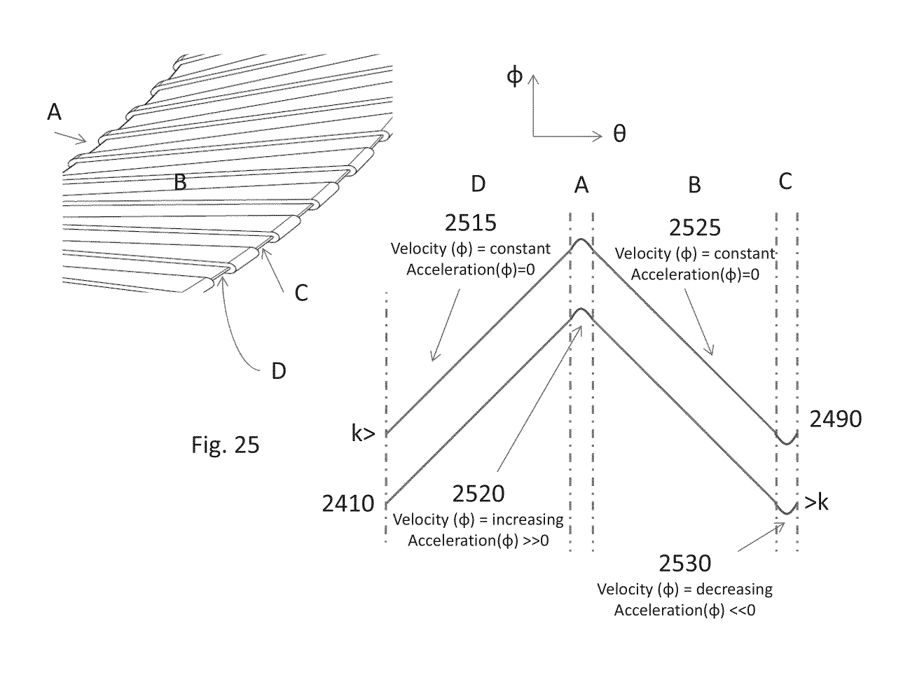

However, the velocity and acceleration are not constant with respect to the toroidal angle φ. Referring now to FIG. 25, in face D, the linear nature of the wire 710 pathway maintains acceleration with respect to toroidal angle φ at zero (acceleration(φ)=0), but maintains a velocity (as previously established) with respect to toroidal angle φ. In face A, the abrupt curve induces a considerable acceleration with respect to toroidal angle φ (acceleration(φ)>>0), which increases the velocity. In face B, the linear nature of the wire 710 pathway returns acceleration with respect to toroidal angle φ at zero (acceleration(φ)=0), but maintains the velocity (as previously established at face A). In face C, the abrupt curve—which is in the opposite direction with respect to toroidal angle φ as compared to face A—induces a considerable deceleration with respect to pitch angle φ (acceleration(φ)<<0).

Overall, the net acceleration with respect to toroidal angle φ around the entire winding of wire 710 is zero. Since the total acceleration with respect to toroidal angle φ around the turn is equal to zero, the field generated by the cooper pair acceleration is equal to the field generated by the cooper pair deceleration; thus again a net zero.

However, while the fields may be equal, they do not have equal effects on rotor 230. Specifically, the face A defines a zone of acceleration that is proximate to rotor 230. In contrast, the face C defines a zone of deceleration that is further away from rotor 230. Since the influence of the induced fields on rotor 230 drops off based on the square of distance, the torque applied by the proximate zone of acceleration on face A is far greater than the counter torque applied by the zone of deceleration on face C. Thus, while the total fields are opposite, there is a non-zero net effect on the rotor 230, which exerts a torque to rotate rotor 230.

An approximately 45 degrees angle in grooves 1940 potentially optimizes the acceleration and deceleration of cooper pairs. Specifically, the total torque applied to rotor 230 is based on the number of wires turns on face A and the gravitational forces generated by each individual turn of the wire. A larger angle would have a more pronounced curve on face A that creates a larger force individual force per wire, but the architecture would reduce the number of wire turns that could fit on toroid winding support element 1930. Conversely, a smaller angle provides more wire turns, but each turn has a less pronounced angle with respect to phi and thus generates less force. That being said, the invention is not limited to any particular angle and angles of approximately 5, 10, 15, 20, 25, 30, 35, 40, 45, 50, 55, 60, 65, 70, 75, 80, and 85 can be used, with each ±5 degree variance.

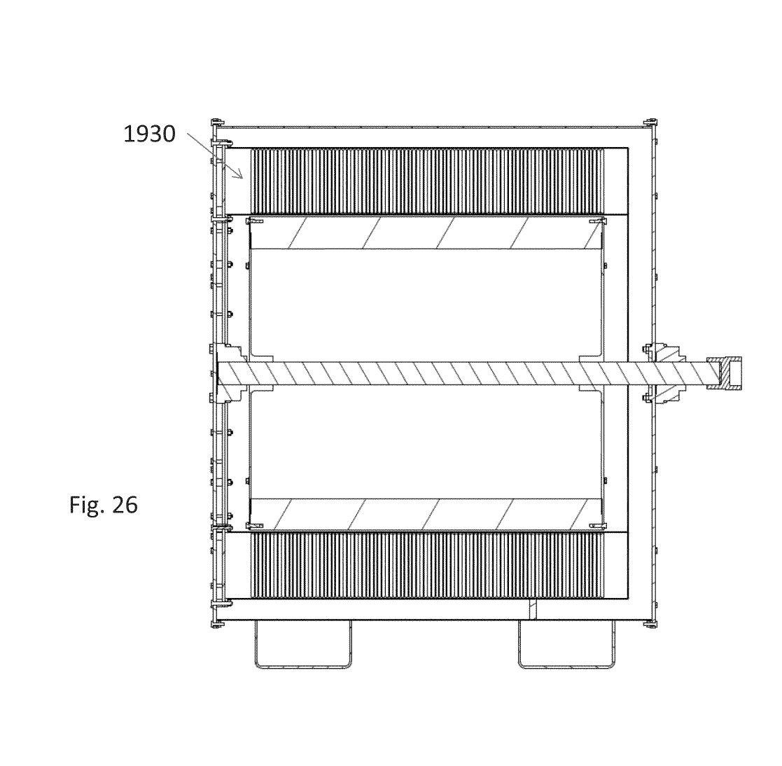

As noted above, FIG. 19 shows the toroid winding support dements 1930 spaced apart. FIG. 26 shows an embodiment with the toroid winding support element 1930 much closer together, which allows for considerably more toroid winding support elements 1930 in the design. Although given the site of toroid winding support element 1930 any gaps there between may not be visible, it is to be understood that such gaps may be present such as shown in FIG. 2, and may be maintained by ceramic spacers; these gaps allow the refrigerant to circulate.

Toroid winding support element 1930 preferably has an inner radius of 50 cm, an outer radius of 70 cm, and a thickness of 5 mm. Grooves 1940 are preferably recessed by a distance w into the outer skin of toroid winding support element 1930. These dimensions are only exemplary, and other configurations could be used.

The above embodiments are discussed in relation to a scientific postulate that deceleration of cooper pairs induces a field which is opposite that of the acceleration, and thus induces a counter-torque on the rotor. This postulate is based on a perception that acceleration with respect to the angle φ is a primary component of the formation of the fields. However under an alternative scientific postulate the radial acceleration with respect to the radial angle θ is also a primary component of the formation of the fields. Under this postulate there is no deceleration of the cooper pairs with respect to θ, but rather only areas of inward radial acceleration that induce a common field that combines in the torque effect on the rotor. The structure of the embodiments above are the same regardless of which postulate is considered, although under the alternative postulate the resulting power may be higher because there may be more torque.

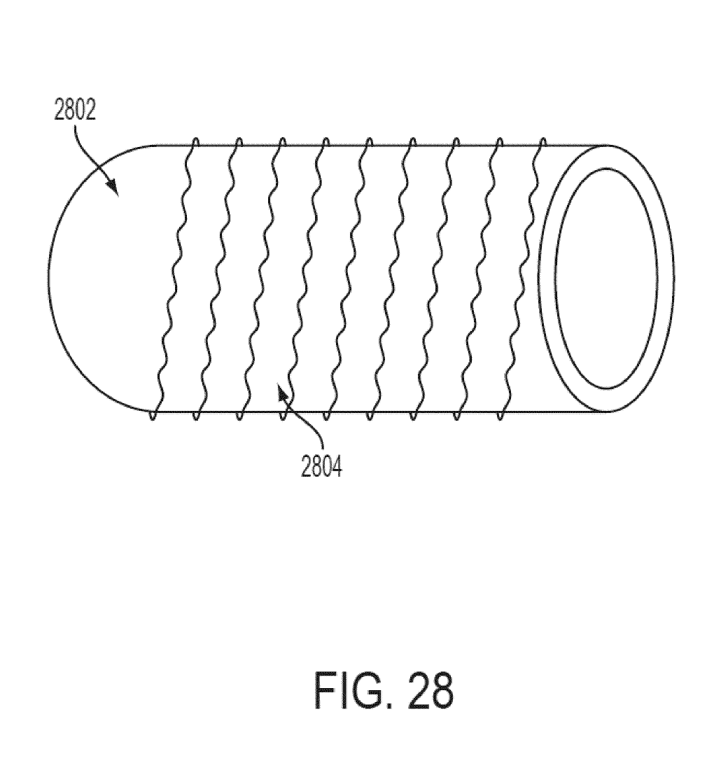

According to another embodiment of the invention shown in FIG. 28, which is particular to the alternative scientific postulate, the cross section of the toroid 2802 is significantly thinner than as discussed with respect to prior embodiments, and potentially on the order of about 1-5 mm in thickness. At this thickness, the toroid 2802 would to the eye appear to have an overall hollow cylinder shape, and such shape is to be understood to fall within the scope of toroid as used herein. By using a relatively thin toroid 2802 as compared to other embodiments herein, the of acceleration of the cooper pairs are very close to the underlying rotor, and thus exert a relatively high amount of torque as compared to a more distal relationship (where the torque would reduce with respect to distance).

Preferably only one toroid 2802 would be used, although several toroids could be connected together and/or adjacent over the length of the rotor to form a collective overall toroid 2802. The configuration of the support architecture and motor would be the same as shown in e.g., FIGS. 1-6, appropriately sized for the smaller toroid 2802.

The superconducting wire 2804 is wrapped around the outer surface of toroid 2802 in a pattern for the conductive portion that that resembles a meandering line, in that the conductive pattern has a back and forth, zig-zag, or wave shape rather than a straight line. FIG. 28 shows a single winding around the toroid 2802 with three turns having significant spacing between each turn, although it is to be understood as per embodiments above that the turns of wires are typically much close together (and may be touching), and overlap each other as the windings form layers over each other going back and forth over the toroid 2802.

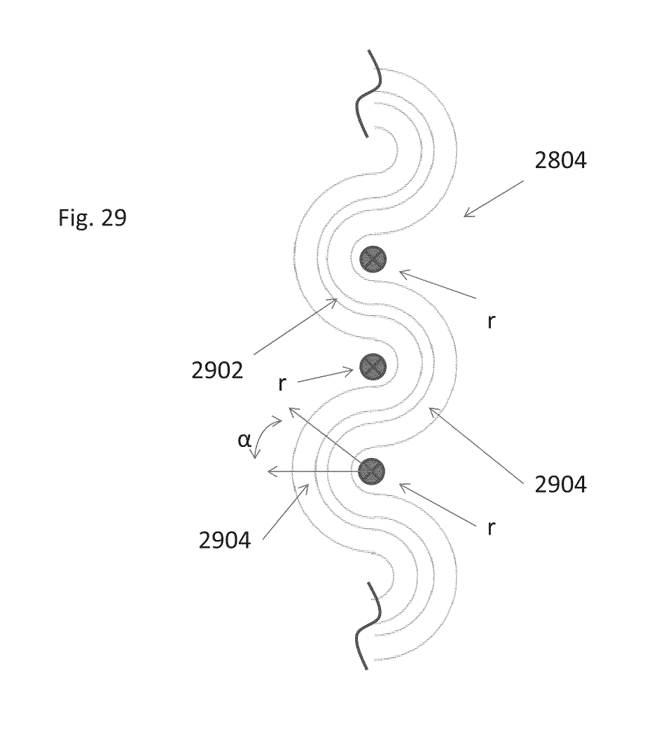

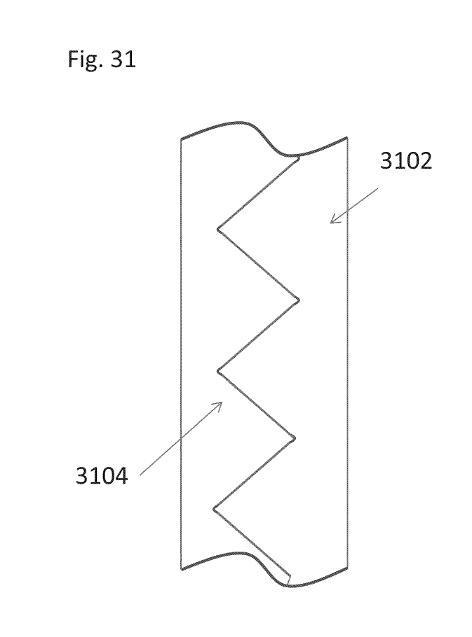

FIG. 29 shows a zoomed in portion of the wire 2804, and demonstrates the meandering underlying conductive pattern 2902 within the insulation 2904 as repeatedly curving in a wave portion. However, the invention is not limited to any particular type of meandering pattern. For example, straighter lines with more abrupt transitions for a more traditional overall zig-zag pattern as seen in FIG. 31 could also be used.

Relative to each back and forth in the meander, there is a radial axis r (FIG. 5, and shown by an encircled x in FIG. 29) that extends through the toroid 2802 to the center of the device. Relative to that axis r, the cooper pairs moving through the conductive path will have an acceleration with respect to the rotation in the angle alpha α around radial axis r. The magnitude of acceleration at any particular point on the meander will be based in part on the rate of change of alpha, which is dictated by the shape of the meander. Thus, tighter turns in the meander pathway will produce higher acceleration than straighter areas. For a symmetrical wave pattern, the acceleration would be substantially constant with respect to α because the turns have the same shape. The magnitude of the resulting field is a function of, inter alia, the magnitude of the acceleration with respect to α at any particular point along the meander.

The wire 2804 is preferably wound as a helix in one direction as shown in FIG. 28, and then overlapped with another layer in a reverse direction, etc. However, the invention is not so limited, and other patterns may be used. As discussed with respect to other embodiments, the wire 2804 may be a single wire wrapped around toroid 2802 over and over, or may be a combination of smaller overlapping wires.

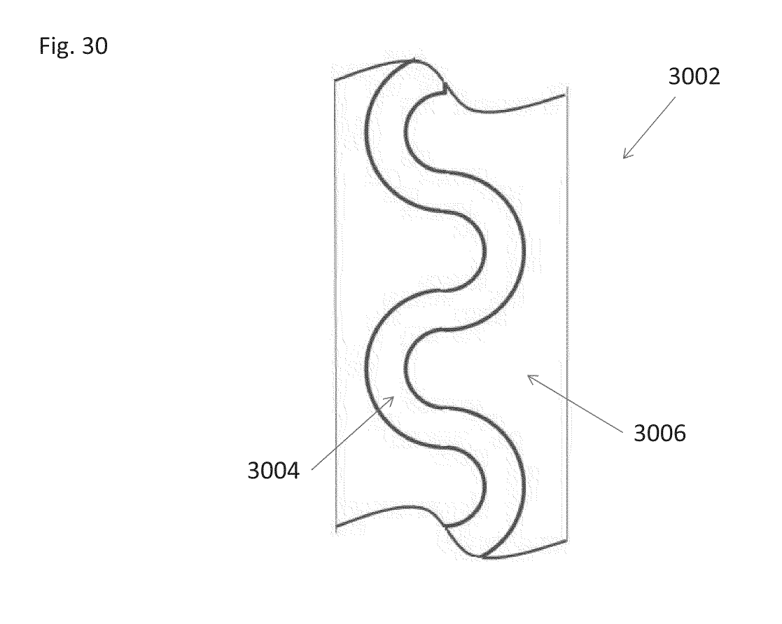

Wire 2804 may be a typically superconducting wire made from materials as discussed herein and laid in the noted patterns, and the conductive pattern follows the shape of the wire itself. In another embodiment that employs thin films as in FIG. 30, a thin film wire 3002 itself may have a different pattern than the imbedded thin film superconducting conductive path 3004 within the insulating portion 3006. Specifically, the conductive path 3004 within a thin film wire is partially customizable, in that shapes other than the exterior shape of the wire can be used as the conductive path, such as shown in FIG. 30. Thus, the wire 2804 itself while overall straight, may therefore have a meandering internal conductor 3002 within an otherwise straight wire path. FIG. 31 shows a similar design with wire 3102 and conductive path 3104. In the embodiment above, the wire 2804 itself would thus have, e.g., a helix configuration around the toroid 2802 that did not appear to the eye to be meandering, with instead the meandering pattern being embedded in the thin film structure.

In the symmetrical wave meander of the conductive pattern in FIG. 31, the acceleration is substantially constant throughout the entire pathway. In a different pattern, such as the zig-zag in FIG. 31, the acceleration would not remain constant.

In implementation, for thin film wires, the thickness of the wire (including insulators and support metals) is preferably about 100 microns, the width is preferably about 4 mm, and the conductive pattern within the thin film is preferably about 1 micron thick and preferably about 1.5 mm wide. Preferably there is no space between the wires, although this need not be the case. As a practical matter, the wires could be laid as close as possible in as many turns as possible from one end to the other of the toroid 2802, and then overlapped in multiple layers as many times as possible subject to physical limitations of the materials. For example, for a 1 meter toroid 2802, there could be 250 turns per layer end to end, with 100 or more layers.

If the entire winding assembly has the current going in a common direction, it may generate an undesirable magnetic field that could limit performance. To address this, at least some portion of the wiring pattern, and preferably substantially half of the pattern, carries current in an opposite direction from the remainder of the wiring pattern. One way this could be done is to repeatedly lay two sets of wires in alternative layers in the same wiring pattern. The ends of the two wires are then connected to different terminals of the current source, such that one each of the two layers provide the same wiring pathway but in opposite direction. The extent of the opposite direction offsets the creation of the undesirable magnet field; and this can be minimized if not outright eliminated by proper balancing of the wire layout.

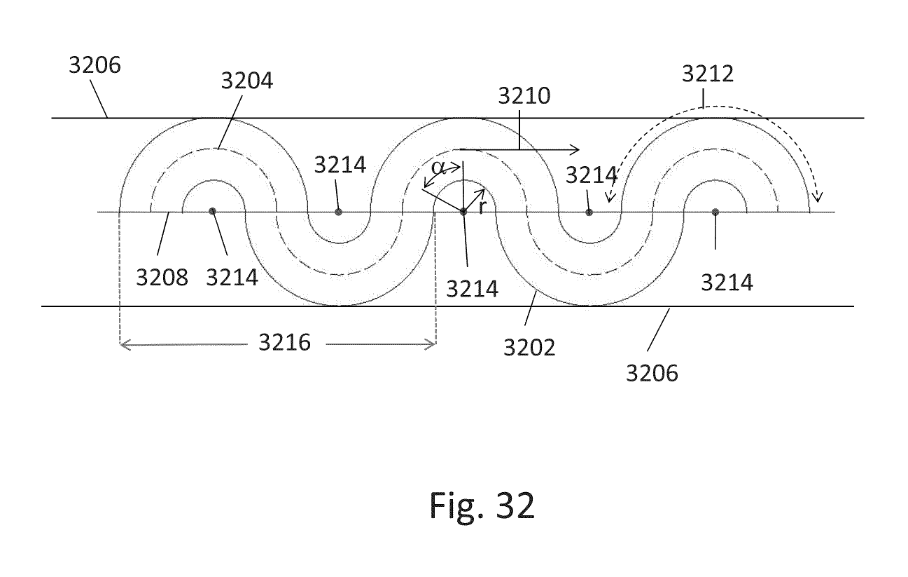

Alternate geometries of superconductive material may be used to the ones discussed above. FIG. 32 illustrates a serpentine pattern 3902 similar in overall geometry to that shown in FIG. 29 with additional labels to assist with terminology for discussing traces of superconductor material formed on a substrate (as contrasted with discrete wires). The “trace” means a structure made of conductive material. “Motif” means a repeating geometric shape of a trace. “Trace axis” means a one-dimensional tine or curve 3204 generally along the center of the trace (and may thus not be straight as in a traditional axis). “Envelope” means a conceptual boundary 3206 within which trace oscillates. “Envelope axis” means a one-dimensional line or curve 3208 generally along the center of the envelope (which need not be straight). “Instantaneous alignment” means the instantaneous direction 3210 of the trace pattern, typically a tangent to a curved trace axis. “Turn,” when referring to a portion of a trace pattern, means a portion 3212 in which the instantaneous alignment changes monotonically in a single direction (e.g., making a clockwise change before making a counter-clockwise change, or vice versa). A turn “focus” is a point 3214 around which a pattern changes direction. The variable “r” or term “turn radius” means a distance from a turn focus to a characteristic point on the pattern, such as a closest point on the pattern or on the pattern axis. The variable alpha (α) means an angle through which a trace pattern turns. “Tape” means a trace on a substrate and includes a structure having a trace, a substrate, and additional components. “Section” means a unitary portion 3216 of a trace formed as a single, non-repeated motif shape (e.g., a full single cycle of a motif in a trace)”. “Segment” means a portion of a trace made of plural sections. “Trace pattern” refers generically to the shape of a trace.

The trace pattern 3202 of FIG. 32 has a generally serpentine shape composed of a series of alternating turns. In each turn, the trace axis instantaneous alignment makes a semi-circular turn of approximately 180 degrees in a first direction. In a subsequent turn, the instantaneous alignment rotates approximately 180 degrees in the opposite direction. FIG. 32 labels the last turn 3212. The motif of FIG. 32 is characterized as a section of two turns with curved edges, with the first turn being in a first direction, and the second turn being in the opposite direction. The motif can be repeated an arbitrary number of times. The number of repetitions will be determined by the needs of the application in which the trace will be used. The envelope axis 3208 is generally straight. (Other motifs will be described with differing numbers of turns and outlines.)

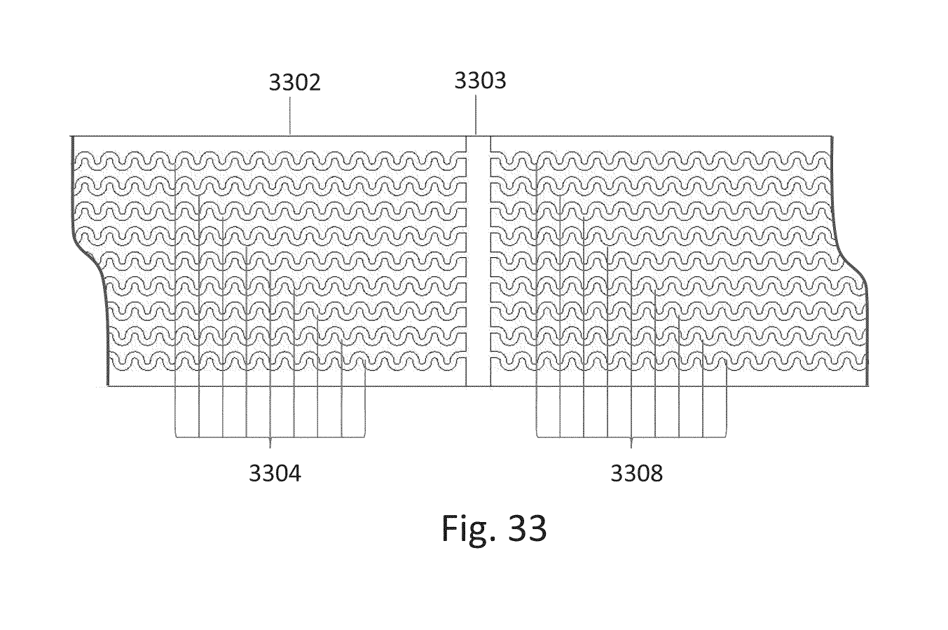

FIG. 33 illustrates a substrate 3302 supporting several parallel trace segments 3304. Each segment 3304 is a series of repeating two-turn sections using the motif of FIG. 32. The particular example shows nine trace segments 3304. Each segment has about fifteen, two-turn sections. The two-turn sections of each trace segment 3304 are part of an electrically continuous pathway. (It will be understood that the terms “clockwise” and “counterclockwise” may depend on the frame of reference, and the use of the terms are interchangeable, provided that the direction of turn alternates.) The number of repeating sections and the number of trace segments may be varied according to application.

The nine trace segments 3304 may optionally be electrically connected in parallel to one another by a landing 3303. An additional set of trace segments 3308 also connect to the landing 3308. The landing 3303 electrically connects the first set of segments 3304 in series with the second set of segments 3308. Landings 3308 are optional but offer a benefit in case of a defect in any trace segment that causes an open circuit or otherwise impedes current flow. In such a case, current will be carried in undamaged parallel segments and, at a landing 3303, the current will be redistributed in the following set of trace segments.

Landing 3303 will preferably be made of the same superconducting material as the trace segments 3304. Spacing between landings 3303 maybe based on quality of the manufacturing process, such as to be spaced sufficiently that the likelihood of two failed segments between landings 3303 is sufficiently low. Landings 3303 preferably would be provided at least once each meter of trace length, although the invention is not limited to the presence and/or placement of landings.

Superconducting traces made with the motif shown in FIGS. 32 and 33 will exhibit field effects useful for a variety of applications, including generation of rotational torque and thrust. The intensity of the field increases as the turn radius decreases, therefore, smaller trace radii are generally preferred. Traces made with the motif of FIG. 32 may have sub-millimeter turning radius on the order of 100 s of microns or less, preferably on the order of 10 s of microns or less, and most preferably on the order of one microns or less.

By way of non-limiting example, an embodiment containing 10 serpentine traces of 100 micron width and 100 micron spacing across a 4 mm substrate may generates a field significantly stronger (potentially 10 times larger) than a single trace of 1 millimeter width. Similarly, the field can be scaled by reducing the trace conductor width and spacing to 10 microns or to 1000× by reducing the patterned width and spacing to 1 micron.

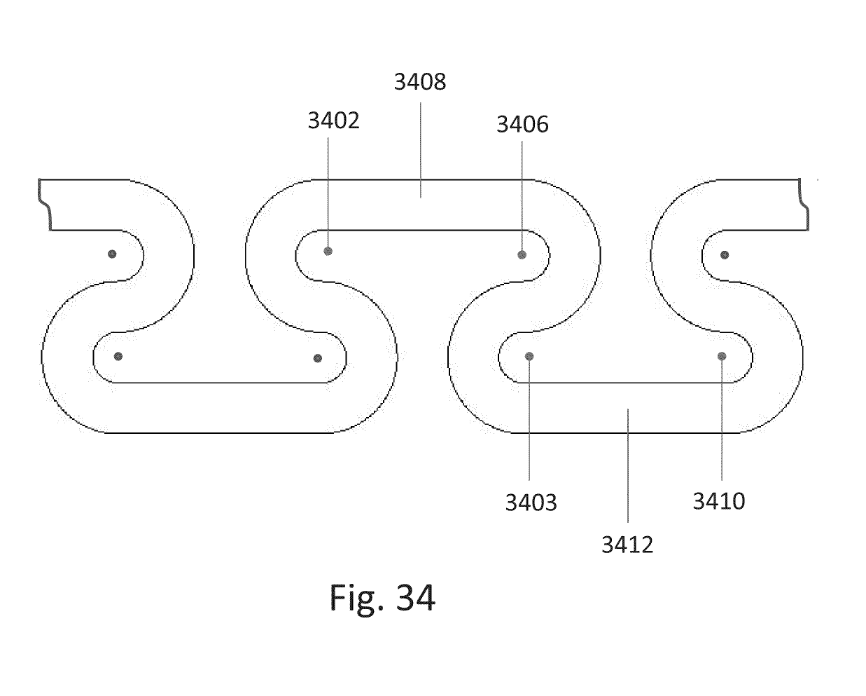

FIG. 34 illustrates a trace pattern 3412 with an alternative, 4-turn motif. In this motif, a first turn of a first (e.g., clockwise) direction about a first focus 3402 is followed by a straight portion 3408 and then a second turn of the same (e.g., clockwise) direction about a second focus 3406. This first pair of turns about foci 3402, 3406 is followed by a second pair of turns of the opposite (e.g., counterclockwise) direction about foci 3403, 3410. For the motif of FIG. 34, a single trace section would have four turns, and the sections may be repeated an arbitrary number of times. Distinguishing characteristics of the motif are that the trace pattern uses sections having four turns, and the outlines of the turns are curved.

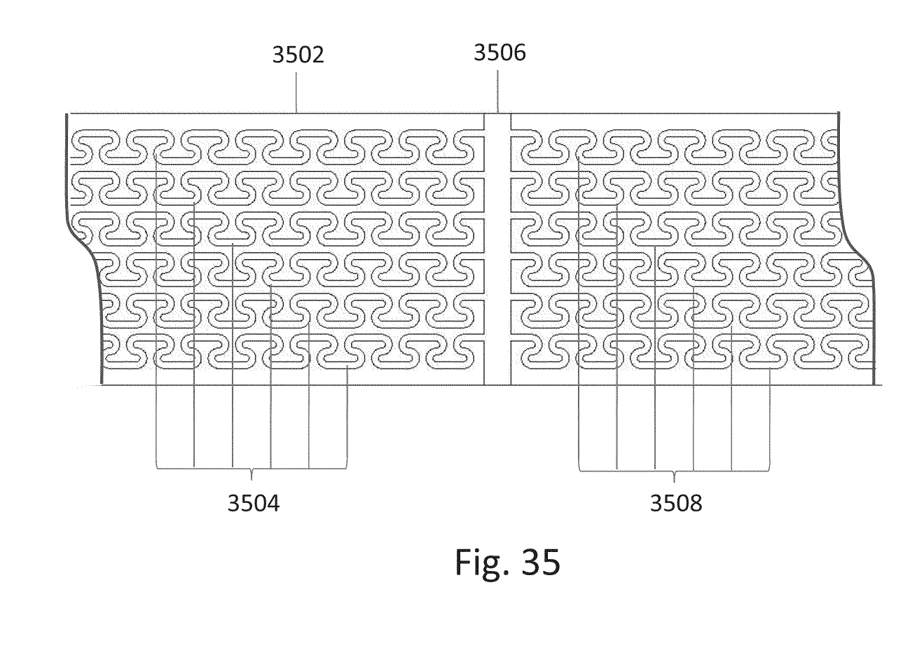

FIG. 35 illustrates a substrate 3502 supporting several parallel trace segments 3504. Each segment 3504 is a series of repeating four-turn sections using the motif of FIG. 34. The particular example shows six parallel trace segments 3504, each having about eight, four-turn sections, although the invention is not so limited. The four-turn sections are electrically connected in series with one another. The six trace segments 3504 may be electrically connected in parallel with one another by a landing 3506. The number of 4-turn sections may be varied according to application. An additional set of trace segments 3508 may also connect to the landing 3506. The landing 3506 electrically connects the first set of trace segments 3504 in series with the second set 3508.

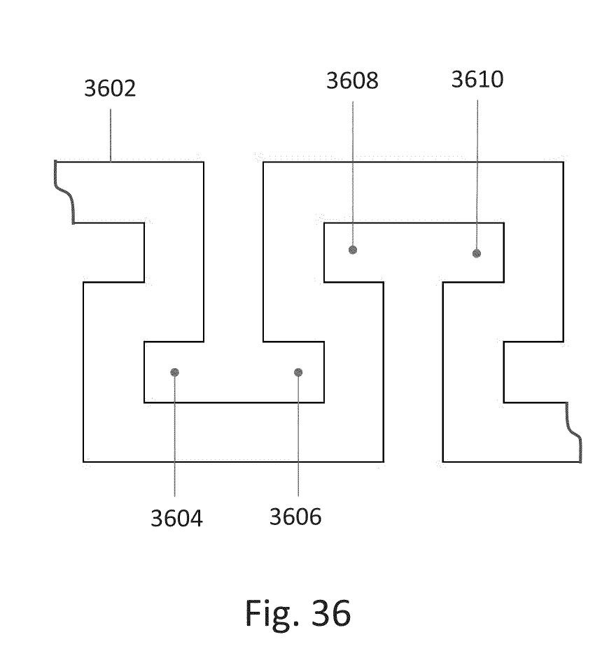

FIG. 36 illustrates a trace pattern 3602 having an alternative, rectilinear motif. The motif is similar to the 4-turn motif of FIG. 34 in that a section is made of four turns, with two turns of a first turn direction about foci 3604, 3606 followed by two turns of a second turn direction about foci 3608, 3610. A turn of FIG. 36 differs from that of FIG. 34 in that a rectilinear turn is made of rectangular portions rather than continuously varying curves. Distinguishing characteristics of the motif are that a section has four turns, and the outlines of the turns are straight.

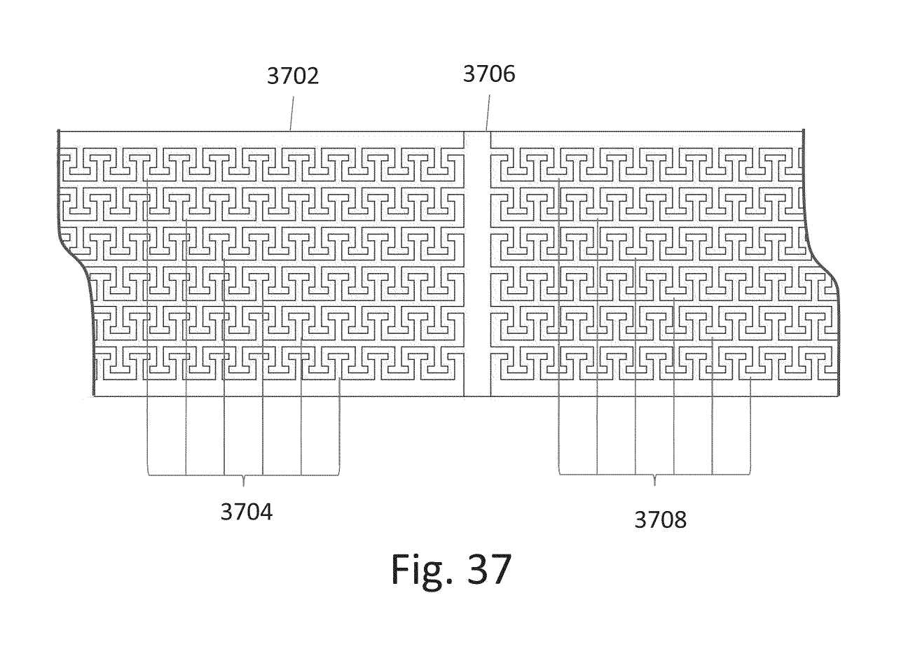

FIG. 37 illustrates a substrate 3702 supporting several parallel trace segments 3704. Each segment is a series of repeating four-turn sections of the motif of FIG. 36. The particular example shows six parallel trace segments 3704, each having about ten four-turn sections, although the invention is not so limited. The four-turn sections are electrically continuous. The six trace segments 3704 may be electrically connected in parallel with one another by a landing 3706. The number of 4-turn sections may be varied according to application. An additional set of trace segments 3708 may also connect to the landing 3706. The landing 3706 electrically connects the first set of trace segments 3704 in series with the second set 3708. For a rectilinear trace pattern, the envelope axis may be a line, curve, or series of lines or curves passing through the turn foci. Separation distance of foci preferably is approximately the same as foci for the curved motifs.

The trace patterns of FIGS. 33-37 are all non-limiting examples of “meandering” trace patterns, in that the pathway oscillates back and forth. However, the invention is not so limited to the disclosed shaped, and other meandering designs could be used.

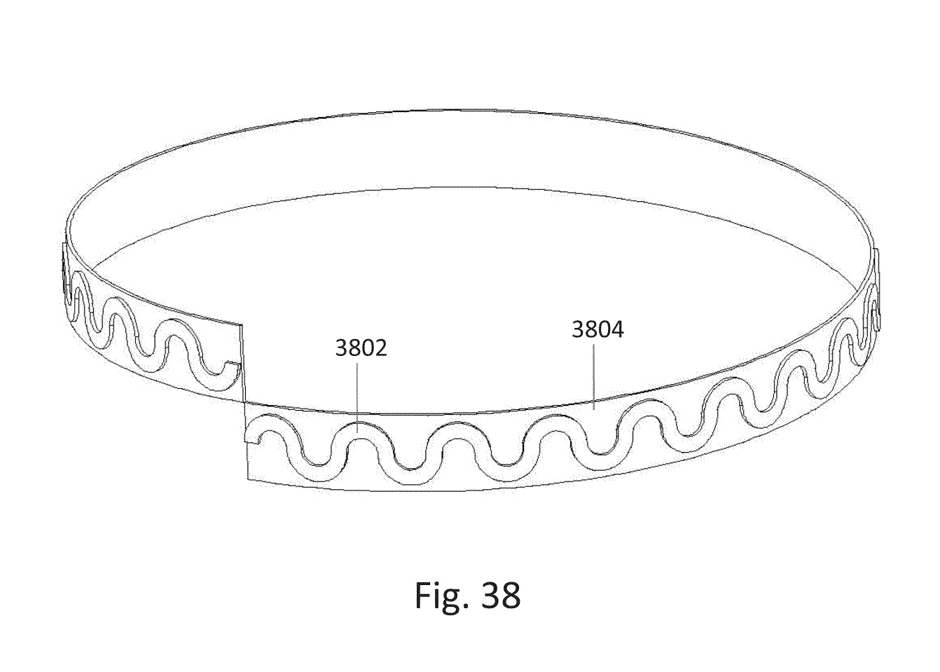

FIG. 38 illustrates a single wrap of a three-dimensional, helical structure based on the trace pattern of FIG. 32. Conceptually, the three-dimensional structure can be imagined as that being the product of (1) forming a flat trace 3802 on a substrate 3804 in the trace pattern of FIG. 32 and then (2) wrapping the trace 3802 and substrate 3804 around, or mapping the trace and substrate onto, a cylinder.

The substrate 3804 is wrapped (or mapped) with the envelope axis along a helical path so that, after a full wrap around the cylinder, the substrate becomes slightly offset from the starting point and can be extended in additional wraps without overlap; the envelope axis is accordingly helical. This conceptual process of wrapping and mapping is only for ease of explanation. It should be understood that the structure may be formed in other ways, and the exact process of forming the structure is not limiting. For example, the trace may also be formed directly onto a cylinder without first forming a planar trace. The helical structure may be based on other trace patterns, such as the trace patterns of FIGS. 34 and 36.

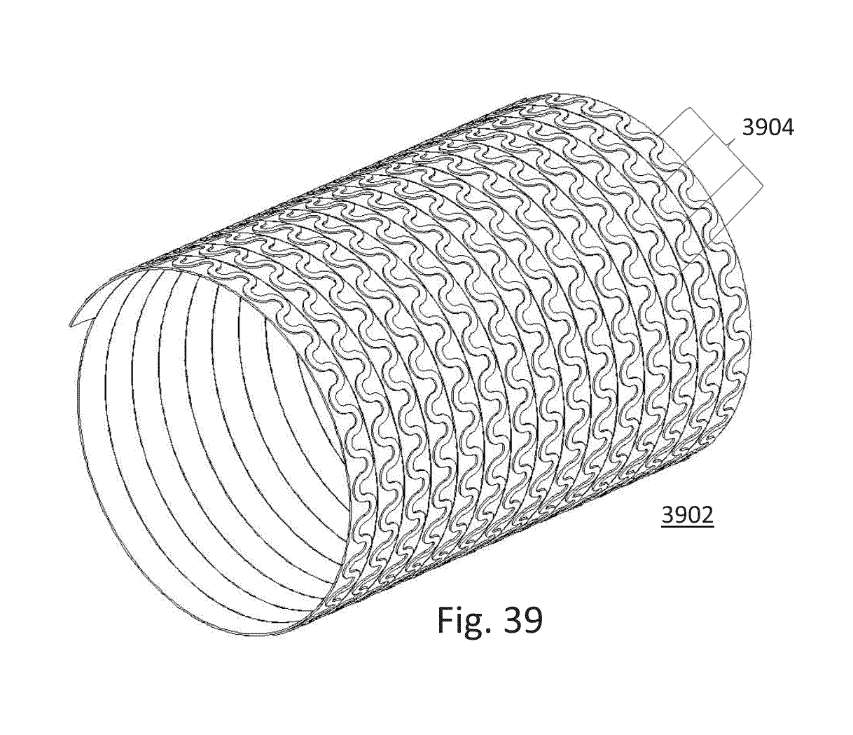

FIG. 39 illustrates an extension 3902 of the helical structure of FIG. 38 with additional wraps 3904 around a geometric cylinder. The particular example shows 15 wraps, but the invention is not so limited and the number of wraps may vary depending on the application. The extension 3902 may be based on other trace patterns, such as the trace patterns of FIGS. 34 and 36. Extension 3902 may also wrap back and forth from the ends to form overlapping layers. In this case the helical structure would extend from one end to the other, then rise up to begin a new layer above a prior layer, and repeat as may be required. At the ends the helical structure may adopt a different shape (e.g., more circular) to accommodate that transition.

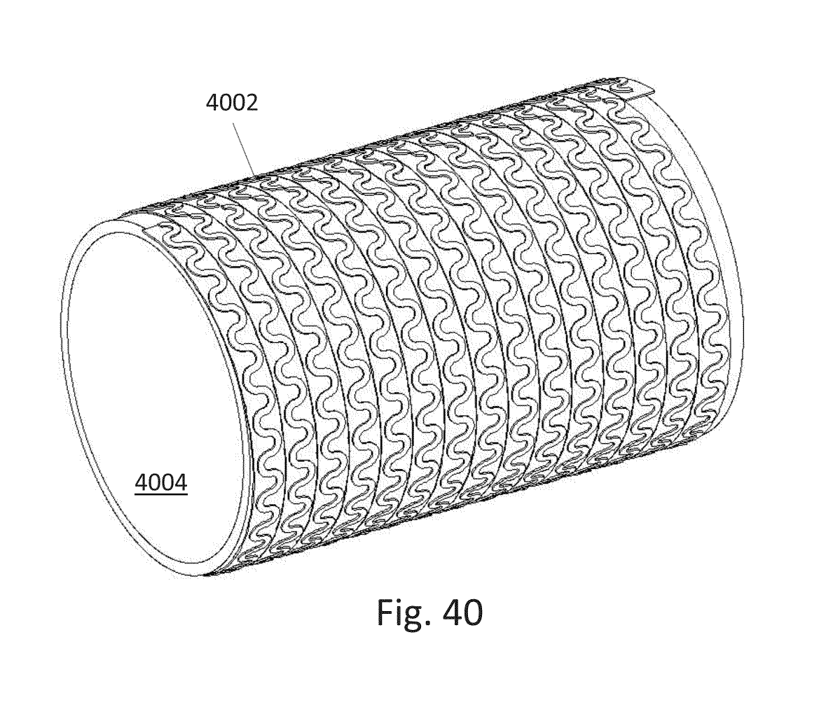

FIG. 40 illustrates the extension 4002 of FIG. 39 as applied to the exterior of a cylindrical frame 4004 for use in a rotating machine, such as machines disclosed elsewhere herein.

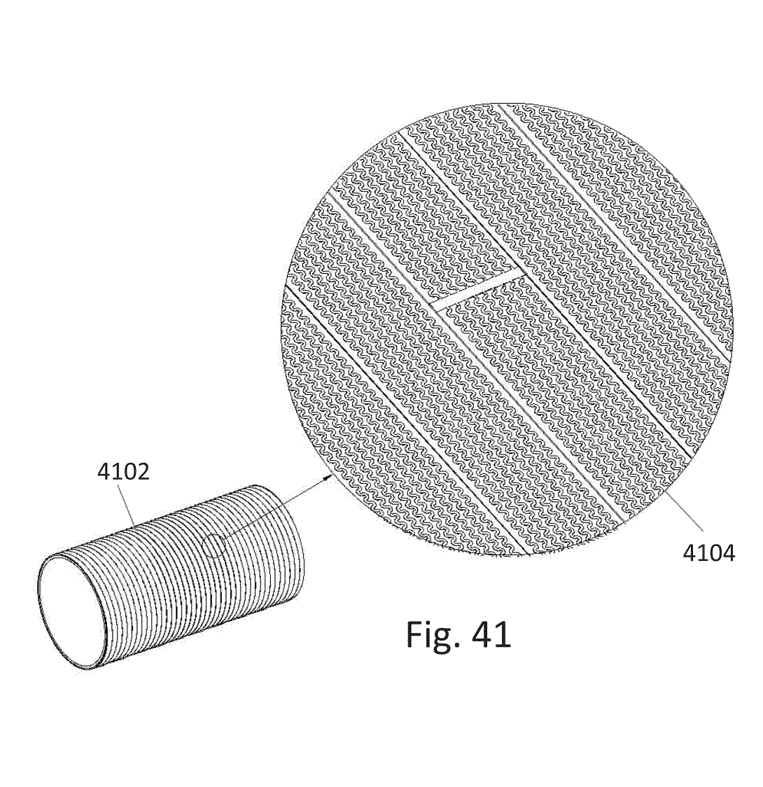

FIG. 41 illustrates an alternate extension 4102 of the helical structure of FIG. 40. In the alternate extension 4102, a trace 4104 as shown in FIG. 33 is used, which has multiple parallel segments on a substrate, instead of the trace of FIG. 32.

Each of FIGS. 33-42 disclose exemplary traces using the same motif throughout, such as consistently using a two-turn motif alone, or consistently using a four-turn motif alone. However, the invention is not so limited. Different motifs can be combined. For example, the two-turn motif in the left portion of FIG. 33 could be connected to the four-turn trace motif in the right portion of FIG. 35. Different adjacent trace paths could also have different motifs.

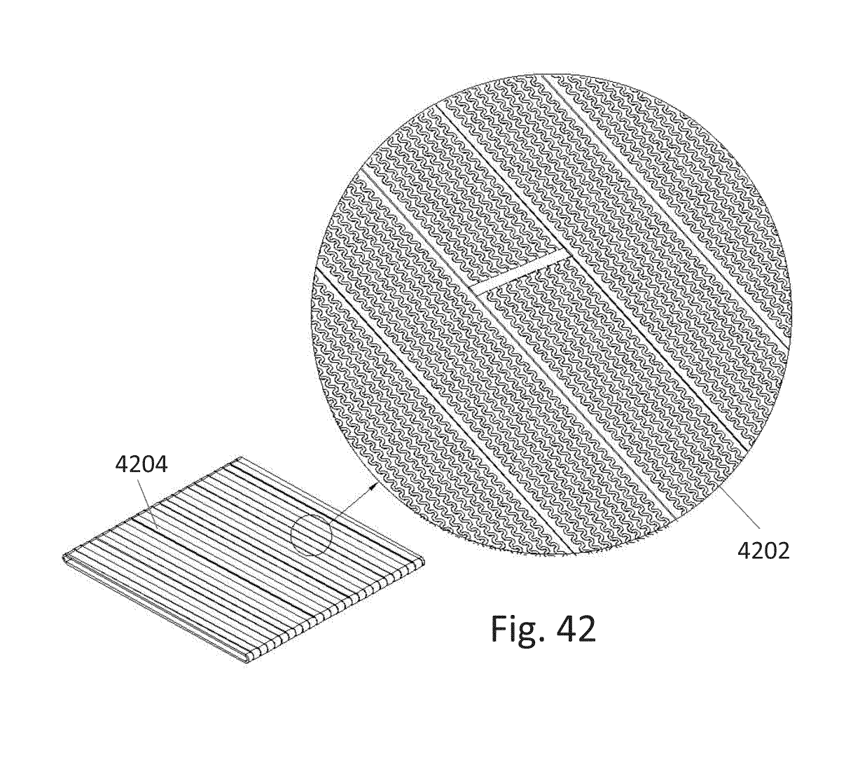

FIG. 42 illustrates an application of trace pattern 4202 of the type illustrated in FIG. 33 applied to a rectangular frame 4104. The trace pattern 4202 may be used in applications where differing geometries of acceleration may be desired. Other trace patterns may be used, such as the trace patterns of FIGS. 34 and 36. FIG. 42 show one complete wrap 4202 around rectangular frame 4204. As discussed above, there may be multiple wraps, e.g., from a substrate carrying traces running back and forth in an overlapping winding.

In the above embodiments, the traces have an elongate, non-linear trace pattern characterized by (i) a trace pattern thickness, (ii) a trace pattern width greater than the trace pattern thickness, (iii) a trace pattern length greater than the trace pattern width, (iv) a trace pattern axis extending along the trace length, and (v) an instantaneous alignment tangential to the trace pattern axis.

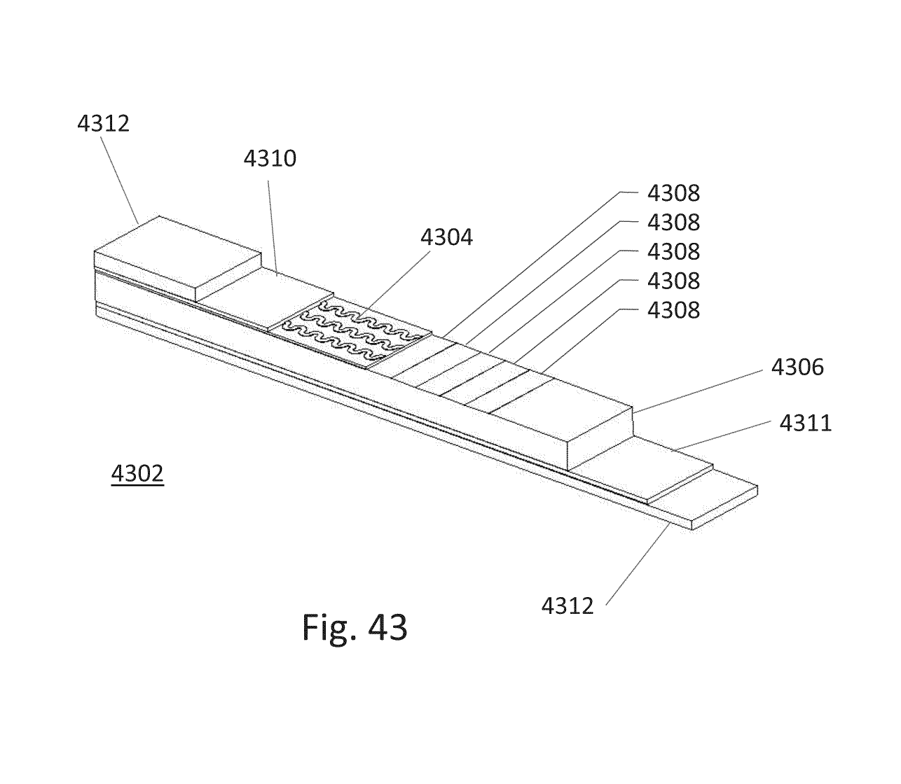

FIG. 43 illustrates a tape structure 4302 for traces 4304 formed on a flexible substrate 4306. The illustrated traces 4304 are based on the motif of FIG. 32, but other motifs may be used, such as the motifs of FIGS. 34-37. FIG. 43 illustrates three trace segments similar to those shown in FIG. 33, but other numbers of trace segments may be used.

The tape structure 4302 may be fabricated on a substrate 4306 preferably made of Hastelloy, a nickel alloy. Other substrate materials can be used. A series of thin-film barrier metals 4308 may be deposited on the Hastelloy to provide a bonding surface for depositing the superconducting film 4304 and to align the grain structure of the superconducting film. A thin film of superconductor, preferably YBCO or other Rare Earth (RE)CBO is deposited on the barrier-metal stack. The YBCO ceramic material preferably has a thickness on the order of 1 micron, although other thicknesses could be used. A silver layer 4311 may be deposited on top of the superconductor to serve as a conductive path for small defects with a second silver layer 4311 below the substrate. The assembly made of the substrate 4306, barrier stack 4308, superconductor 4304, and silver 4310, 4311, is plated above and below with copper layers 4312 to form a metal tape with embedded, patterned superconductor. The metal tape may be formed initially in widths of about 4 mm, or formed in larger (e.g., 12 mm widths) and cut to about 4 mm. Other widths can be used.

The superconductor layer can be patterned photolithographically or by direct write. For purposes of this application, direct write laser processing is preferred. The trace may be patterned by using a laser to ablate the silver, superconductor and barrier-metal layers to remove unwanted material in the voids between traces. An insulator may then be deposited to fill voids, and the assembly then plated by copper. The superconductive traces all would be internal to the copper and not seen by visual inspection.

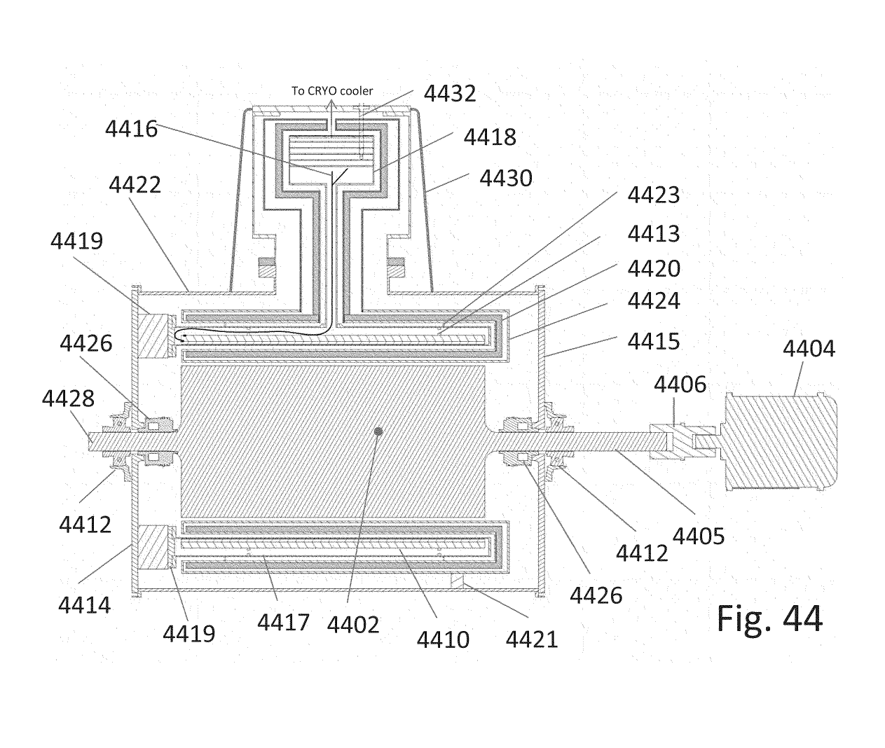

FIG. 44 illustrates a cross section of an alternate energy transfer device, including a rotor 4402 coupled to a generator 4404 through a first shaft 4405 and shaft coupler 4406. The rotor 4402 preferably is a solid block of metal, such as stainless steel but may also be assembled from plates mounted on a shaft and locked together by bolts to simplify final assembly, or in other ways with other materials. Support bearings 4412 mounted to front and rear endplates 4414, 4415 allow rotation of the rotor 4402. Endplates 4414, 4415 also may serve as mounting stands. The bearings are preferably superconducting magnetic bearings, but other bearing types may be utilized.

A winding 4410 made of superconductive material patterned with traces as discussed above forms a cylindrical solenoid outside of, and concentric with the rotor 4402. Winding leads 4416, preferably made of copper, connect the solenoid to a power supply (not shown). Endplates 4414, 4415 and case 4422 form a hermetically sealed cryostat.

A liquid helium container 4417 having a generally toroidal shape encapsulates the solenoid winding 4410. Liquid helium from a cryogenic cooler (not shown) fills a reservoir 4418 and the helium container 4417, thus cooling the windings 4410 to 4 degrees kelvin. The liquid helium container 4417 mounts through a helium container to endplate 4419 and ceramic standoffs 4424 to a cryostat endplate 4414. Winding centering rings 4413 position the winding 4410 within the liquid helium container 4417.

A gas container 4424 wraps around and encompasses the liquid helium container 4417 both on the interior side (between the liquid helium container 4417 and the rotor 4402) and on the exterior side (between the liquid helium container 4417 and the case 4422). The gas container 4424 also extends around the liquid helium reservoir 4418. MLI insulation batting 4420 within the gas container 4424 insulates the liquid helium container 4417 and reservoir 4418. The batting insulation 4420 may be clad on both sides by one or more layers of Mylar for additional thermal protection. The gas container 4424 mounts to an endplate 4414 through a cantilever support 4421 that extends partially as an arc around a portion of the bottom of the gas container 4424. Spacer rings 4423 center the liquid helium container 4417 within the gas container 4424.

The cryostat endplates 4414, 4415 and case 4422 form a hermetic chamber which preferably is evacuated. The first shaft 4405 and a second shaft 4428 pass through vacuum seals 4426 to maintain the integrity of the chamber. The vacuum seals are preferably Ferrofluid vacuum seals utilizing magnetic fluid. The rotor 4402 turns within this vacuum, so that vacuum separates the rotor 4402 from the gas container 4424. The vacuum impedes heat transfer from the rotor 4402 to the gas container 4424. The vacuum also impedes heat transfer from the gas container 4424 to the liquid helium container 4417. Similarly, vacuum impedes heat transfer from the case 4422 to the gas container 4424.

A chimney structure 4430 on top of the case 4422 houses the liquid helium reservoir 4418 and portions of the gas container 4424. An electrical connector 4432 penetrates the chimney 4430 for connections to the winding leads 4416.

The embodiment of FIG. 44 operates consistent with other embodiments herein, in that in operation injection of a current into the patterned superconducting material establishes a field that imparts a rotational torque on the rotor. Energy from the rotor is useful for any machine that can be powered by a rotating shaft, including but not limited to turning an electric generator, locomotion, or any other rotating machine.

A cryogenic refrigerator (not shown) maintains cryogenic temperatures required for superconducting operation. Preferably, a two-stage refrigerator may be used for cooling the helium to a liquid state and maintaining the temperature of the 40 degree kelvin gas container. However, other configurations may be used, such as ones having larger cryogenic reservoirs for meeting shorter term mobile requirements.

The assembly is depicted in FIG. 44 with the rotor shaft parallel to the surface of the earth. However, this is not a limiting configuration. This device can be configured with a rotor shaft perpendicular to the surface of the earth by using a magnetic levitation bearing, or other bearing structure to support the weight of the rotor and modifications as required to the helium reservoir to support vertical configuration.

The embodiments herein are directed toward the application of generating fields to induce torque in the rotor that is used to drive a power generator. However, the invention is not so limited. Any environment could represent a possible application, including but not limited. to energy generation, communications, or remote imaging.

It will be apparent to those skilled in the art that modifications and variations may be made in the systems and methods of the present invention without departing from the spirit or scope of the invention. It is intended that the present invention cover the modifications and variations of this invention provided they come within the scope of the appended claims and their equivalents.

We claim:

1. A trace comprised of superconductive material,
the trace having an elongate, non-linear trace pattern characterized by (i) a trace pattern thickness, (ii) a trace pattern width greater than the trace pattern thickness, (iii) a trace pattern length greater than the trace pattern width, (iv) a trace pattern axis extending along the trace length, and (v) an instantaneous alignment tangential to the trace pattern axis;
said trace pattern further characterized by (i) an envelope within which the trace pattern oscillates and (ii) an envelope axis extending along a centerline of the envelope;
said trace comprising at least two electrically continuous sections, where each section includes (i) a first turn in which the trace pattern instantaneous alignment changes about 180 degrees in a first direction around a first turn focus, and (ii) a second turn in which the trace pattern instantaneous alignment changes about 180 degrees in a second direction, opposite the first direction, about a second turn focus, and wherein a turn radius is less than about 1000 microns.
